(19) United States
(12) Patent Application Publication
(10) Pub. No.: US 2014/0123895 A1
(43) Pub. Date: May 8, 2014

(54) PLASMA PROCESS APPARATUS AND PLASMA GENERATING DEVICE

(71) Applicant: Tokyo Electron Limited, Tokyo (JP)

(72) Inventors: Hitoshi KATO, Iwate (JP); Shigehiro MIURA, Iwate (JP)

(73) Assignee: Tokyo Electron Limited, Tokyo (JP)

(21) Appl. No.: 14/063,039

(22) Filed: Oct. 25, 2013

(30) Foreign Application Priority Data
Nov. 5, 2012 (JP) 2012-243814

(51) Int. Cl. H01J 37/32

(52) U.S. Cl. CPC H01J 37/32339
USPC 118/697; 118/723 VE

(57) ABSTRACT

A plasma process apparatus includes a vacuum chamber; a substrate holder configured to hold a substrate; a gas supplying part configured to supply a plasma generating gas into the vacuum chamber; an antenna configured to be supplied with a high-frequency power and generate an electromagnetic field for generating plasma of the plasma generating gas; a Faraday shield disposed between the antenna and an area where the plasma is generated and composed of a conductive plate where a plurality of slits, which extend in a direction that intersects with an extending direction in which the antenna extends and are arranged in the extending direction of the antenna, are formed to block an electric field in the electromagnetic field and to allow a magnetic field in the electromagnetic field to pass therethrough; and an adjusting part composed of a conductive material and configured to adjust an opening area of the slits.

### CROSS-REFERENCE TO RELATED APPLICATION

The present application is based upon and claims the benefit of priority of Japanese Patent Application No. 2012-243814, filed on Nov. 5, 2012, the entire contents of which are incorporated herein by reference.

### BACKGROUND OF THE INVENTION

1. Field of the Invention

An aspect of this disclosure relates to a plasma process apparatus and a plasma generating device.

2. Description of the Related Art

Japanese Laid-Open Patent Publication No. 2011-40574 discloses a film deposition apparatus that forms, for example, a thin film of silicon nitride (Si—N) on a substrate such as a semiconductor wafer (which is hereafter simply referred to as a “wafer”). The film deposition apparatus employs an atomic layer deposition (ALD) method in which different types of process gases (or reaction gases) that react with each other are supplied in sequence onto a surface of a wafer to deposit a reaction product. The film deposition apparatus includes a vacuum chamber, a rotary table on which wafers are placed, and multiple gas nozzles that face the rotary table and are arranged along the circumferential direction of the vacuum chamber. Plasma areas for reforming a reaction product using plasma are provided between the gas nozzles.

With the film deposition apparatus, each wafer is moved by the rotary table around the center of the rotary table. Therefore, the angular speed of a part (inner part) of the wafer closer to the center of rotation of the rotary table is different from the angular speed of another part (outer part) of the wafer closer to the outer end of the rotary table. For example, the angular speed of the inner part of the wafer is about three times lower than the angular speed of the outer part of the wafer. As a result, plasma irradiation time for the inner part of the wafer becomes longer than plasma irradiation time for the outer part of the wafer. For this reason, depending on the type of a process, the degree (level or strength) of plasma processing may become uneven in the radial direction of the rotary table. Also, the amount of generated plasma and the distribution of plasma in the vacuum chamber may vary depending on a process recipe including a process pressure in the vacuum chamber and the value of high-frequency power for generating plasma.

Meanwhile, Japanese Laid-Open Patent Publication No. 2008-288437 discloses a Faraday shield, and Japanese Laid-Open Patent Publication No. 2008-248281 discloses an adjuster 31 for changing impedance. However, neither one of them discloses a technology for adjusting the degree of plasma processing.

### SUMMARY OF THE INVENTION

An aspect of this disclosure provides a plasma process apparatus that includes a vacuum chamber; a substrate holder disposed in the vacuum chamber and configured to hold a substrate; a gas supplying part configured to supply a plasma generating gas into the vacuum chamber; an antenna configured to be supplied with a high-frequency power and generate an electromagnetic field for generating plasma of the plasma generating gas; a Faraday shield disposed between the antenna and an area where the plasma is generated and composed of a conductive plate where a plurality of slits, which extend in a direction that intersects with an extending direction in which the antenna extends and are arranged in the extending direction of the antenna, are formed to block an electric field in the electromagnetic field generated by the antenna and to allow a magnetic field in the electromagnetic field to pass therethrough; and an adjusting part composed of a conductive material and configured to adjust an opening area of the slits.

### BRIEF DESCRIPTION OF THE DRAWINGS

FIG. 1 is a cut-away side view of an exemplary plasma process apparatus;

FIG. 2 is a cut-away plan view of the plasma process apparatus;

FIG. 3 is a cut-away plan view of the plasma process apparatus;

FIG. 4 is an enlarged cut-away side view of a plasma generating chamber of the plasma process apparatus;

FIG. 5 is a perspective view of the plasma generating chamber;

FIG. 6 is a perspective view of a part of the plasma generating chamber;

FIG. 7 is a perspective view of a part of the plasma generating chamber;

FIG. 8 is an exploded perspective view of the plasma generating chamber;

FIG. 9 is an exploded perspective view of the plasma generating chamber;

FIG. 10 is a perspective view of a Faraday shield of the plasma generating chamber;

FIG. 11 is a side view of the Faraday shield;

FIG. 12 is a plan view of the plasma generating chamber;

FIG. 13 is a perspective view of a shutter for adjusting the area of slits of the Faraday shield;

FIG. 14 is a cut-away side view of a secondary plasma generator of the plasma process apparatus;

FIG. 15 is an exploded perspective view of the secondary plasma generator;

FIG. 16 is a plan view of the secondary plasma generator;

FIG. 17 is a cut-away side view of the plasma process apparatus along a circumferential direction;

FIG. 18 is a drawing used to describe operations of the plasma process apparatus;

FIG. 19 is a drawing used to describe operations of the plasma process apparatus;

FIG. 20 is a drawing used to describe operations of the plasma process apparatus;

FIG. 21 is a drawing used to describe operations of the plasma process apparatus;

FIG. 22 is a drawing illustrating a variation of the plasma process apparatus;

FIG. 23 is a drawing illustrating a variation of the plasma process apparatus;

FIG. 24 is a drawing used to describe operations of a variation of the plasma process apparatus;

FIG. 25 is a drawing used to describe operations of a variation of the plasma process apparatus;

FIG. 26 is a drawing illustrating a variation of the plasma process apparatus;

FIG. 27 is a drawing illustrating a variation of the plasma process apparatus;

FIG. 28 is a drawing illustrating a variation of the plasma process apparatus;

FIG. 29 is a drawing illustrating a variation of the plasma process apparatus;

FIG. 30 is a drawing illustrating a variation of the plasma process apparatus; and

FIG. 31 is a drawing illustrating a variation of the plasma process apparatus.

### DESCRIPTION OF THE PREFERRED EMBODIMENTS

Preferred embodiments of the present invention are described below with reference to the accompanying drawings.

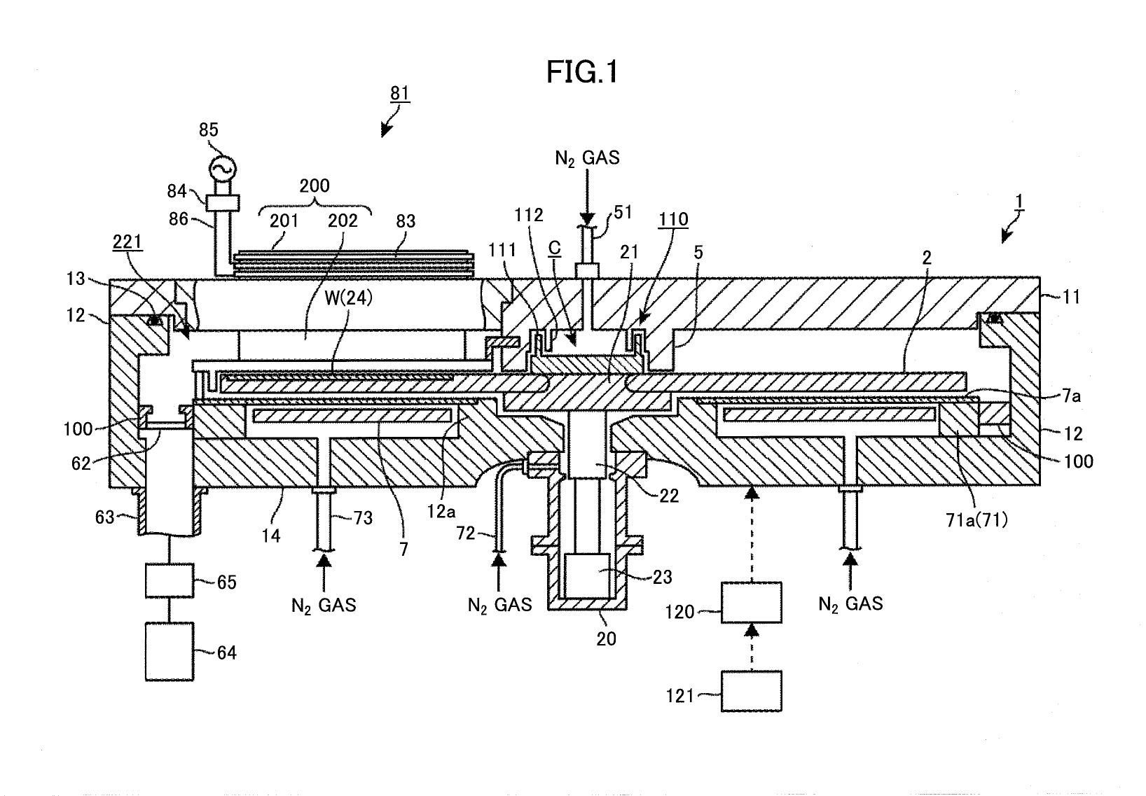

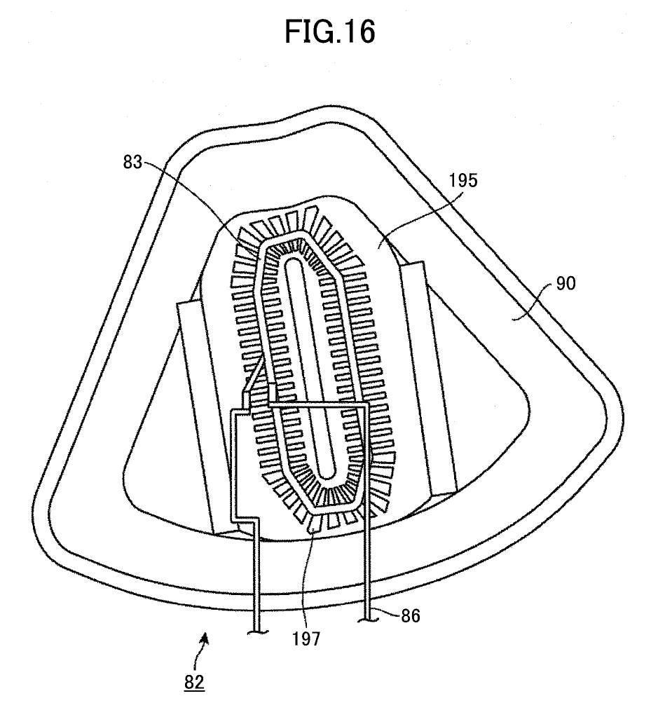

An exemplary configuration of a plasma process apparatus according to an embodiment of the present invention is described below with reference to FIGS. 1 through 17. As illustrated by FIGS. 1 through 3, the plasma process apparatus includes a vacuum chamber 1 having a substantially circular shape in plan view, and a rotary table 2 disposed in the vacuum chamber 1. The center of rotation of the rotary table 2 is at the center of the vacuum chamber. The rotary table 2 is used as a substrate holder on which wafers W are placed. The wafers W are rotated (or moved) by the rotary table 2 around the center of rotation of the rotary table 2. The plasma process apparatus performs plasma processing on the wafers W using plasma of an ammonia (NH₃) gas and is configured to be able to adjust the concentration distribution of the plasma in the radial direction of the rotary table 2. Components of the plasma processing apparatus are described in more detail below.

The vacuum chamber 1 includes a top plate (ceiling) 11 and a chamber body 12. The top plate 11 is detachable from the chamber body 12. A separation gas supplying tube 51 is connected to substantially the center of an upper surface of the top plate 11. The separation gas supplying tube 51 supplies a nitrogen (N₂) gas as a separation gas for preventing different process gases from being mixed with each other in a center area C in the vacuum chamber 1. In FIG. 1, reference number 13 indicates a ring-shaped sealing part (e.g., an O ring) provided along the periphery of the upper surface of the chamber body 12.

A center part of the rotary table 2 is fixed to a core 21 with a substantially cylindrical shape. A rotational shaft 22 is connected to a lower surface of the core 21 and extends in a direction perpendicular to the lower surface of the core 21. The rotational shaft 22 allows the rotary table 2 to rotate (clockwise in this example) about a vertical axis. In FIG. 1, reference number 23 indicates a driving part that is a movement mechanism (or rotating mechanism) for rotating the rotational shaft 22 about the vertical axis, and reference number 20 indicates a case that houses the rotational shaft 22 and the driving part 23. A flange at the upper end of the case 20 is hermetically attached to a lower surface of a bottom 14 of the vacuum chamber 1. A purge gas supplying tube 72 is connected to the case 20. The purge gas supplying tube 72 supplies a nitrogen gas as a purge gas to an area below the rotary table 2. The bottom 14 of the vacuum chamber 14 includes a ring-shaped protrusion 12a that surrounds the core 21 and faces the lower surface of the rotary table 2.

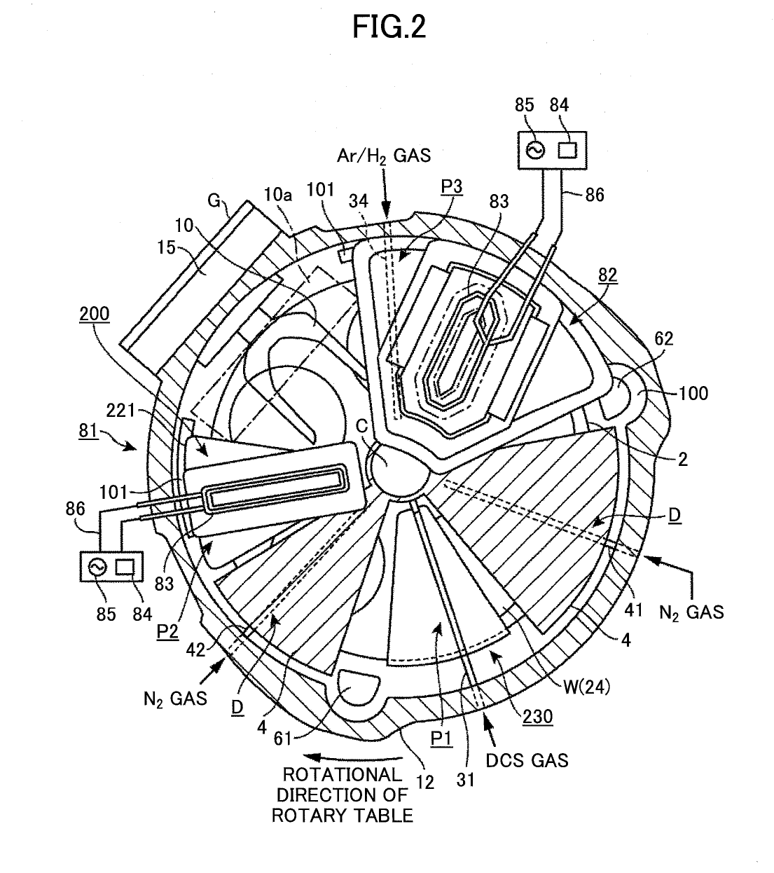

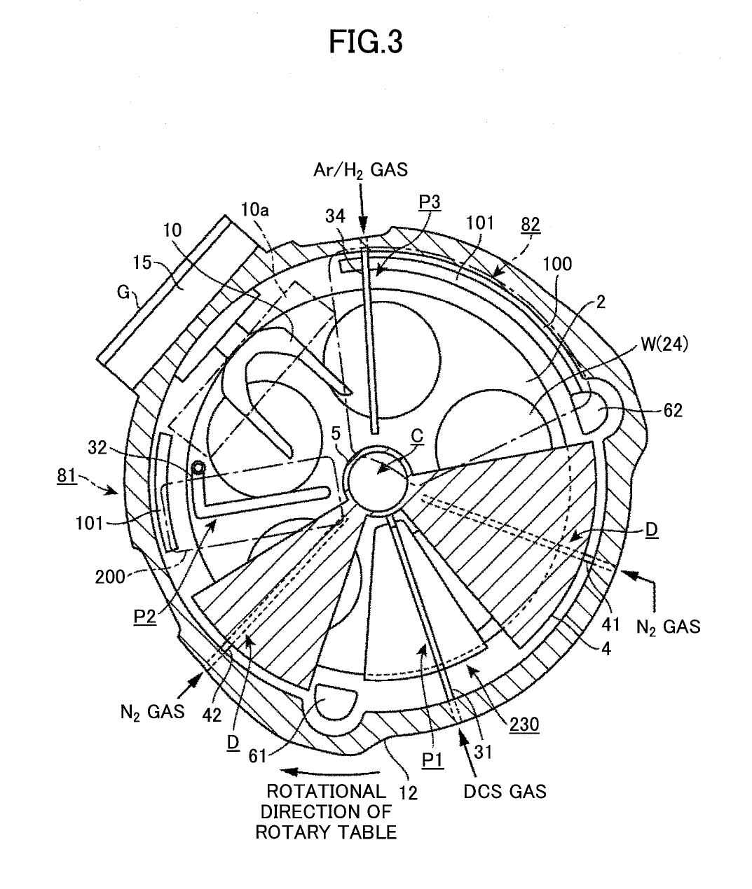

As illustrated by FIGS. 2 and 3, multiple circular recesses 24, which are used as substrate holding areas where the wafers W placed, are formed in the upper surface of the rotary table 2 along the rotational direction (or circumferential direction) of the rotary table 2. In this example, it is assumed that five recesses 24 are formed in the upper surface of the rotary table 2 and the recesses 24 are configured to hold wafers W with a diameter of 300 mm. Through holes (not shown) are formed in the bottom of each recess 24. Three lift pins (described later) move through the through holes to push the under surface of the wafer W and thereby lift the wafer W.

A first process gas nozzle 31, a gas nozzle 34, a separation gas nozzle 41, and a separation gas nozzle 42 composed of, for example, quartz are provided at positions facing areas where the recesses 24 of the rotary table 2 pass through. The nozzles 31, 34, 41, and 42 extend radially and are arranged at intervals along the circumferential direction of the vacuum chamber 1 (or the rotational direction of the rotary table 2). More specifically, the nozzles 31, 34, 41, and 42 extend horizontally from the outer wall of the vacuum chamber 1 toward the center area C such that they face the wafers W on the rotary table 2. In this example, the gas nozzle 34, the separation gas nozzle 41, the first process gas nozzle 31, and the separation gas nozzle 42 are arranged clockwise (along the rotational direction of the rotary table 2) in this order from a transfer opening 15.

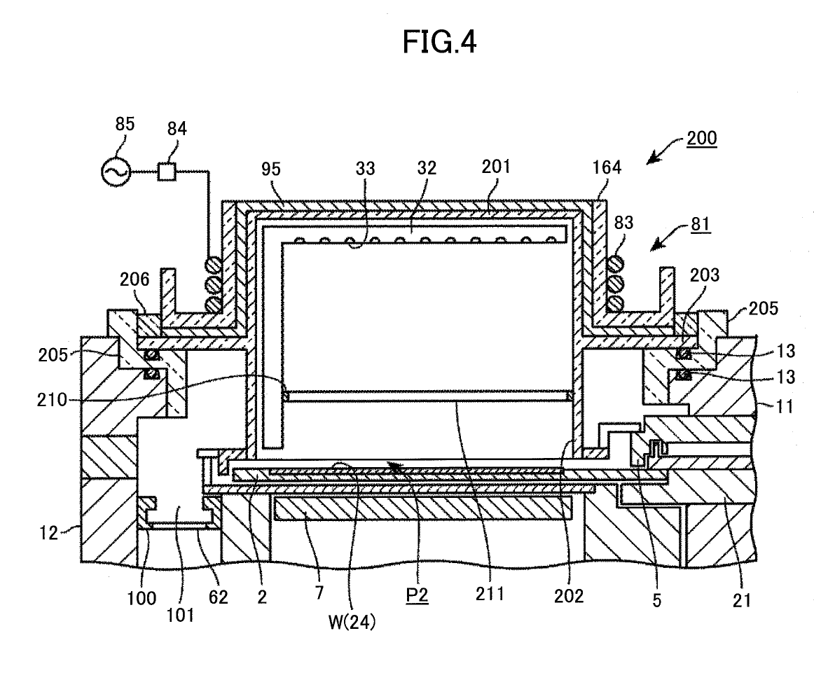

Also, as illustrated by FIG. 4, a primary plasma generating gas nozzle 32, which is used as a plasma generating gas supplying part and composed of, for example, quartz, is provided above the top plate 11 and upstream of the transfer opening 15 in the rotational direction of the rotary table 2 (i.e., between the gas nozzle 34 and the separation gas nozzle 42). The layout of the primary plasma generating gas nozzle 32 above the top plate 11 is described in detail later. In FIGS. 2 and 3, the top plate 11 is omitted. In FIG. 3, the primary plasma generating gas nozzle 32 is illustrated together with the nozzles 31, 34, 41, and 42. In FIG. 3, a primary plasma generator 81, a secondary plasma generator 82, a plasma generating chamber 200, and a housing 90 (which are described later) are omitted for brevity. On the other hand, FIG. 2 illustrates the primary plasma generator 81, the secondary plasma generator 82, the plasma generating chamber 200, and the housing 90 together with other components.

The nozzles 31, 32, 34, 41, and 42 are connected via flow rate controlling valves to gas supplying sources (not shown). The first process gas nozzle 31 is connected to a gas supplying source that supplies a first process gas (e.g., a dichlorosilane (DCS) gas) including silicon (Si). The first process gas may be referred to as a “Si-containing gas”. The primary plasma generating gas nozzle 32 is connected to a gas supplying source that supplies, for example, a mixed gas of an ammonia (NH₃) gas and an argon (Ar) gas. The secondary plasma generating gas nozzle 34 is connected to a gas supplying source that supplies a reforming gas such as a mixed gas of an argon gas and a hydrogen (H₂) gas. The separation gas nozzles 41 and 42 are connected, respectively, to gas supplying sources that supply a separation gas such as a nitrogen gas. The primary plasma generating gas nozzle 32 supplies a second process gas and a primary plasma generating gas. In the descriptions below, for brevity, it is assumed that the primary plasma generating gas nozzle 32 supplies an ammonia gas. Also, instead of an ammonia gas, a gas including nitrogen element (N) such as a nitrogen (N₂) gas may be used.

In the lower surface of each of the nozzles 31, 32, 34, 41, and 42, gas ejection holes 33 for discharging the corresponding gas are formed, for example, at regular intervals along the radial direction of the rotary table 2. Each of the nozzles 31, 34, 41, and 42 is disposed such that its lower surface (lower end or bottom) is at a distance of, for example, about 1 to 5 mm from the upper surface of the rotary table 2.

An area below the first process gas nozzle 31 is a first process area P1 where a Si-containing gas is adsorbed onto the wafer W. An area in the vacuum chamber 1 and below the primary plasma generating gas nozzle 32 is a second process area (plasma generating area) P2 where the components of the Si-containing gas adsorbed onto the wafer W are caused to react with ammonia (more particularly, plasma of an ammonia gas). An area below the secondary plasma generating gas nozzle 34 is a third process area P3 where a reaction product formed on the wafer W that has passed through the first and second process areas P1 and P2 is reformed. The separation gas nozzles 41 and 42 are used to form separation areas D for separating the first process area P1 and the second process area P2.

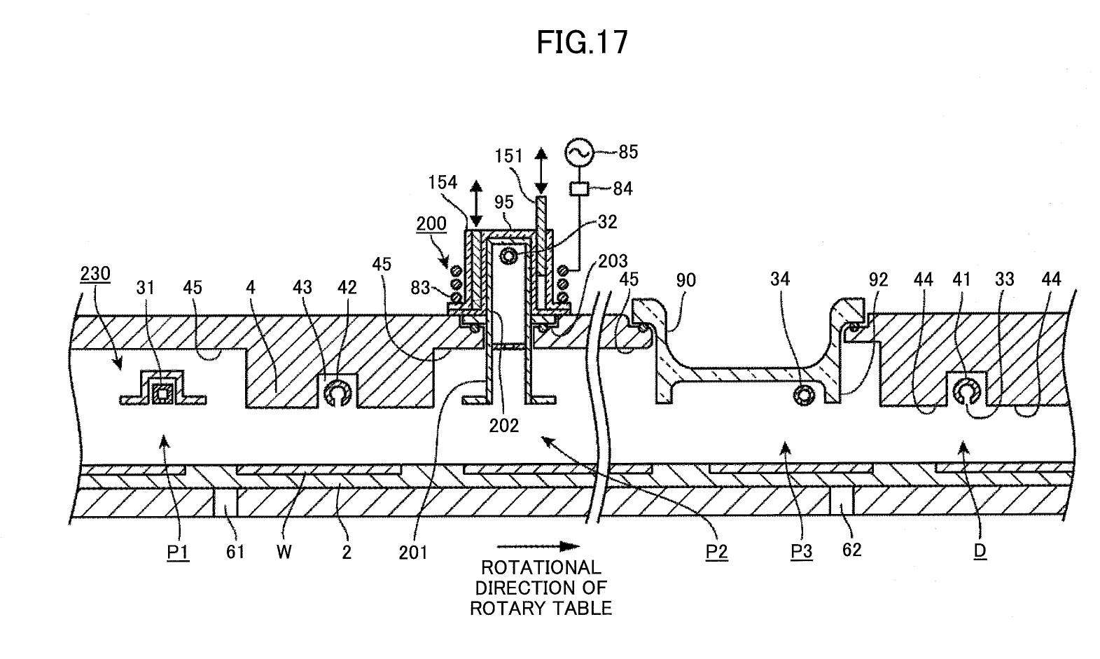

Referring to FIGS. 2 and 3, the top plate 11 of the vacuum chamber 1 includes raised parts 4 having a substantially fan shape and located at positions corresponding to the separation areas D. The separation gas nozzles 41 and 42 are placed in grooves 43 formed in the raised parts 4. As illustrated by FIG. 17, lower ceiling surfaces 44, which are the lower surfaces of the raised part 4, are arranged on both sides of the separation gas nozzle 41 (or the separation gas nozzle 42) in the circumferential direction of the rotary table 2. The lower ceiling surfaces 44 prevent process gases from mixing with each other. Higher ceiling surfaces 45, which are higher than the lower ceiling surface 45, are arranged on both sides of the lower ceiling surfaces 44 in the circumferential direction. The outer end of each raised part 4 (which is near the outer wall of the vacuum chamber 1) is bent to form an L-shape to prevent process gases from mixing with each other. The bent outer end of the raised part 4 faces the outer end face of the rotary table 2, and is at a small distance from the chamber body 12. FIG. 17 is a cut-away side view of the vacuum chamber 1 along the circumferential direction of the rotary table 2.

Next, the layout of the primary plasma generating gas nozzle 32 above the top plate 11 is described. As illustrated by FIGS. 1 and 4-7, the plasma generating chamber 200 is provided in an area where the primary plasma generating gas nozzle 32 is located. The plasma generating chamber 200 protrudes from the vacuum chamber 1 and is shaped like a box with an opening on the lower side. In plan view, the plasma generating chamber 200 is shaped like a flat strip that extends from the center part (center side or inner side) to the outer end (or outer side) of the rotary table 2. The plasma generating chamber 200 may be composed of a material such as quartz or alumina that transmits a high frequency wave. The primary plasma generating gas nozzle 32 is disposed in the plasma generating chamber 200. An upper part of the plasma generating chamber 200, where the primary plasma generating gas nozzle 32 is placed, is disposed higher than the top plate 11. Meanwhile, a lower part of the plasma generating chamber 200 is hermetically inserted into the vacuum chamber 1 from the upper surface of the top plate 11 such that the opening at the lower end of the plasma generating chamber 200 is positioned close to the rotary table 2.

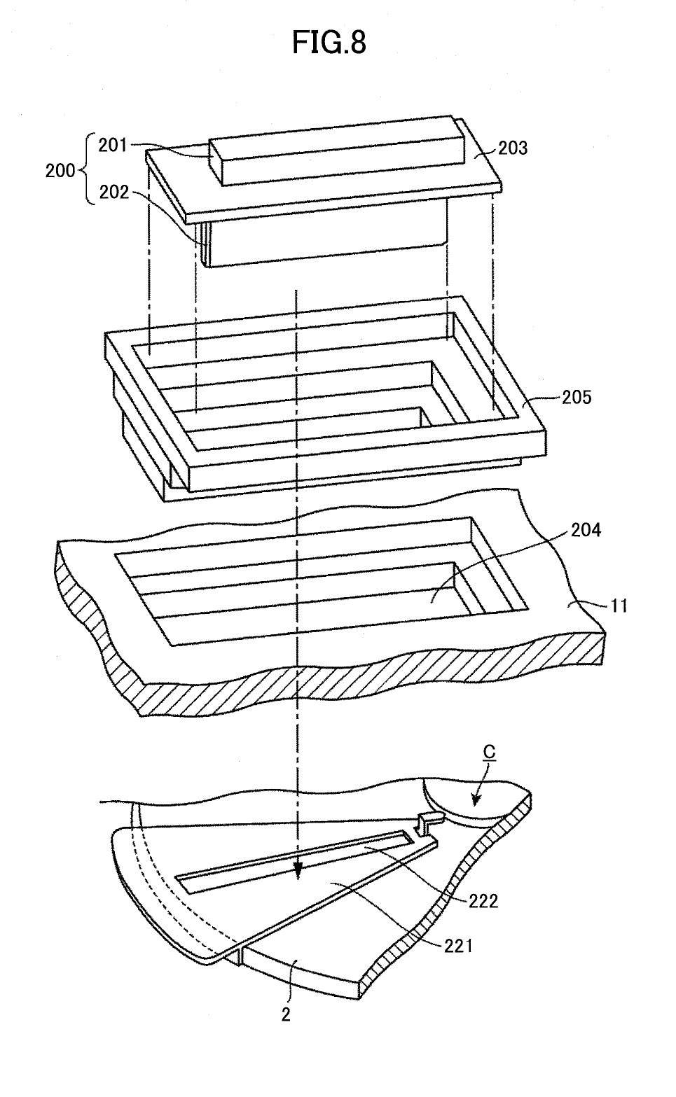

The upper part of the plasma generating chamber 200 is referred to as an upper chamber 201, and the lower part of the plasma generating chamber 200 is referred to as a lower chamber 202. A flange 203 is formed on the outer surface of the plasma-generating chamber 200 at a position between the upper chamber 201 and the lower chamber 201. The flange 203 extends horizontally around the circumference of the plasma generating chamber 200. As illustrated by FIG. 8, an opening 204 for inserting the plasma generating chamber 200 (the lower chamber 202) is formed in the top plate 11. A frame 205 is fitted into the opening 204. The frame 205 is provided to hermetically attach the flange 203 to the top plate 11.

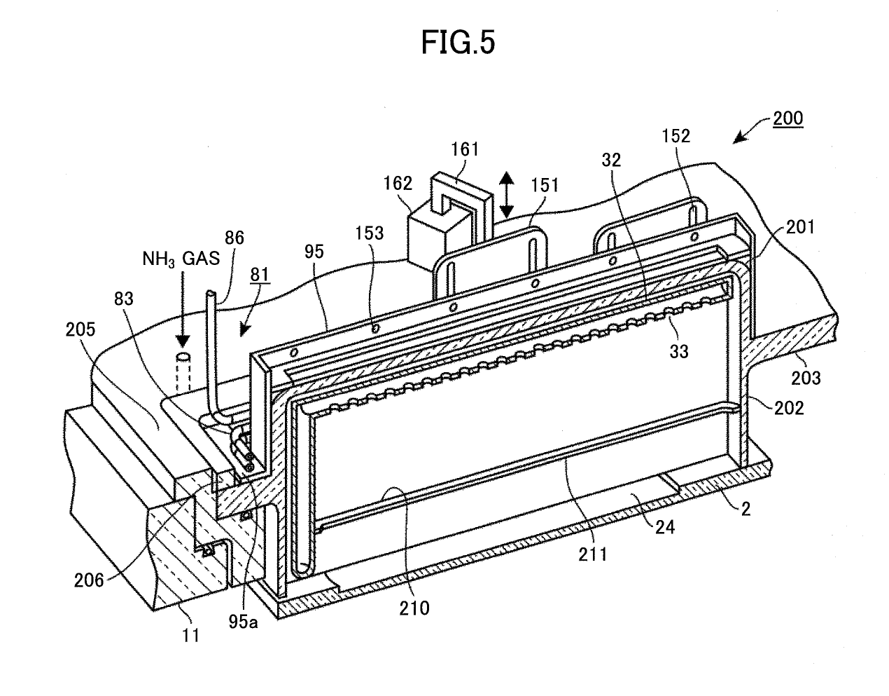

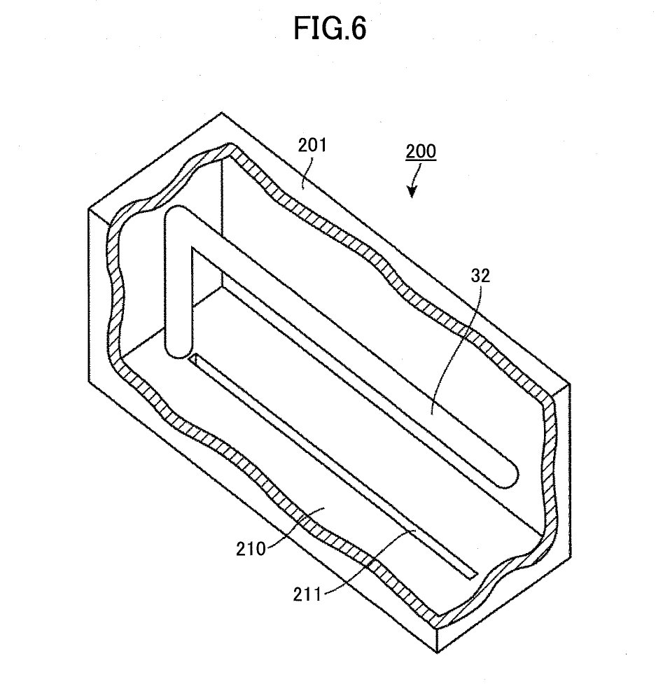

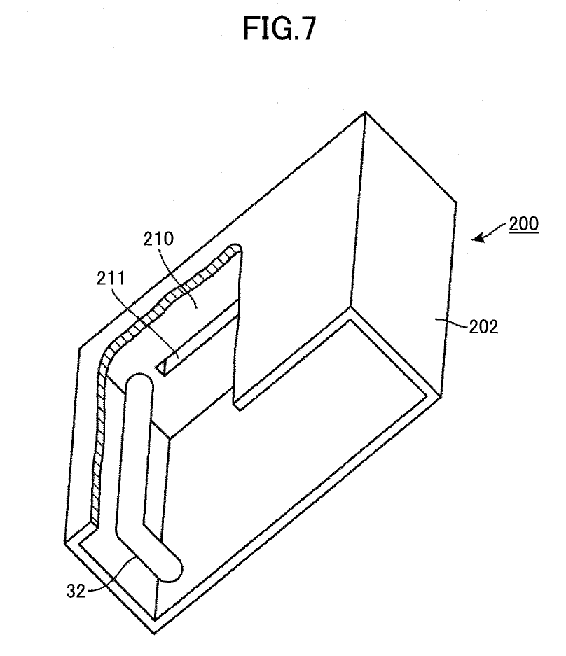

When the plasma generating chamber 200 (including the upper camber 201 and the lower chamber 202) is inserted together with the frame 205 into the opening 204, the flange 203 is hermetically attached via a sealing part 13 to the top plate 11. In FIG. 4, reference number 206 indicates a pressing part for pressing the flange 203 downward to the top plate 11. The pressing part 206 has a substantially circular shape and extends along the outer end of the flange 203. For example, the pressing part 206 is bolted to the vacuum chamber 1. In each of FIGS. 5 through 7, a part of the plasma generating chamber 200 is cut away for illustration purposes. FIG. 6 illustrates the upper chamber 201 seen from above. FIG. 7 illustrates the lower chamber 202 seen from below. In FIG. 8, the sealing part 13 is omitted.

As illustrated by FIGS. 4 through 7, the primary plasma generating gas nozzle 32 is inserted into the plasma generating chamber 200 (the lower chamber 202) at a position that is on a side surface facing downstream in the rotational direction of the rotary table 2 and near the outer side of the rotary table 2, and extends vertically toward the upper chamber 201. The primary plasma generating gas nozzle 32 is bent near the ceiling of the upper chamber 201, and extends horizontally toward the center of rotation of the rotary table 2. The rear end (upstream end) of the primary plasma generating gas nozzle 32 extends horizontally in the rotational direction of the rotary table 2, is bent at substantially right angle to extend upward, passes through the top plate 11, and is connected to a gas supplying source. A partition plate 210, which extends horizontally, is provided in the plasma generating chamber 200 between the upper chamber 201 and the lower chamber 202. The partition plate 210 smoothes the flow of gas (or plasma) and prevents the separation gas from entering into the upper chamber 201.

As illustrated by FIGS. 4 through 7, a discharge opening 211 is formed in the partition plate 210 below the primary plasma generating gas nozzle 32. The discharge opening 211 is shaped like a slit and extends in the radial direction of the rotary table 2, i.e., along the primary plasma generating gas nozzle 32. Because the discharge opening 211 is formed in the partition plate 210, the pressure in the upper chamber 201 can be set independently of the pressure in the vacuum chamber 1.

As illustrated by FIGS. 1 and 8, a fin 221 used as a flow regulating plate is provided around the opening at the lower end of the lower chamber 202. The fin 221 is shaped like a plate and extends along the rotary table 2. The width of the fin 221 increases in a direction from the center side to the outer side of the rotary table 2. Accordingly, the fin 221 is shaped like a fan in plan view. An opening 222 is formed in the fin 221 to prevent the fin 221 from interfering with the lower chamber 202. An end (or the rim) of the fin 221 near the outer side of the rotary table 2 extends downward and faces the outer end face of the rotary table 2. There is a gap between the end of the fin 221 and the outer end face of the rotary table 2. The fin 221 causes plasma, which is discharged from the opening at the lower end of the lower chamber 202 toward the rotary table 2, to flow along the surface of the rotary table 2, and thereby prevents the plasma from being dispersed by the separation gas. The fin 221 is supported by a protrusion 5 and a cover part 7a described later.

The primary plasma generator 81 used as an activating part is provided around the upper chamber 201. The primary plasma generator 81 converts an ammonia gas discharged from the primary plasma generating gas nozzle 32 into plasma. The primary plasma generator 81 includes an antenna 83 that is implemented by metal wire made of, for example, copper (Cu). The antenna 83 is formed, for example, by winding the metal wire three times around a vertical axis. In other words, the antenna 83 is shaped like a coil that surrounds the upper chamber 201. The antenna 83 is connected via a matching box 84 to a high-frequency power supply 85 with, for example, a frequency of 13.56 MHz and an output power of 5000 W. Reference number 86 in FIGS. 1 and 2 indicates connection electrodes for electrically connecting the antenna 83, the matching box 84, and the high-frequency power supply 85.

A Faraday shield 95 shaped like a box with an opening on the lower side is provided between the upper chamber 201 and the antenna 83. The Faraday shield 95 blocks an electric field component of an electromagnetic field (electric field and magnetic field) generated around the antenna 83. When a high-frequency power is supplied to the antenna 83, an electromagnetic field is generated around the antenna 83. When the electric field component in the electromagnetic field reaches the wafer W, the electric field component may electrically damage electric wiring formed in the wafer W. To prevent this problem, the Faraday shield 95 is composed of a metal plate of a conductive material such as copper (Cu) and is grounded. The lower end of the Faraday shield 95 is shaped like a flange that extends horizontally and forms a horizontal surface 95a around the body of the Faraday shield 95. It can be said that the Faraday shield 95 constitutes a part of side surfaces of the upper chamber 201.

As illustrated by FIGS. 9 through 12, slits 97 are formed in side surfaces of the Faraday shield 95 that face upstream and downstream in the rotational direction of the rotary table 2. The slits 97 allow the magnetic field component of the electromagnetic field generated around the antenna 83 to pass through. If the slits 97 are not formed, the magnetic field component is also blocked by the Faraday shield 95 for blocking the electric field component generated around the antenna 83. On the other hand, if the opening area of the slits 97 is too large, in addition to the magnetic field component, the electric field component passes through the Faraday shield 95. For this reason, the opening size and the layout of the slits 97 are determined as described below.

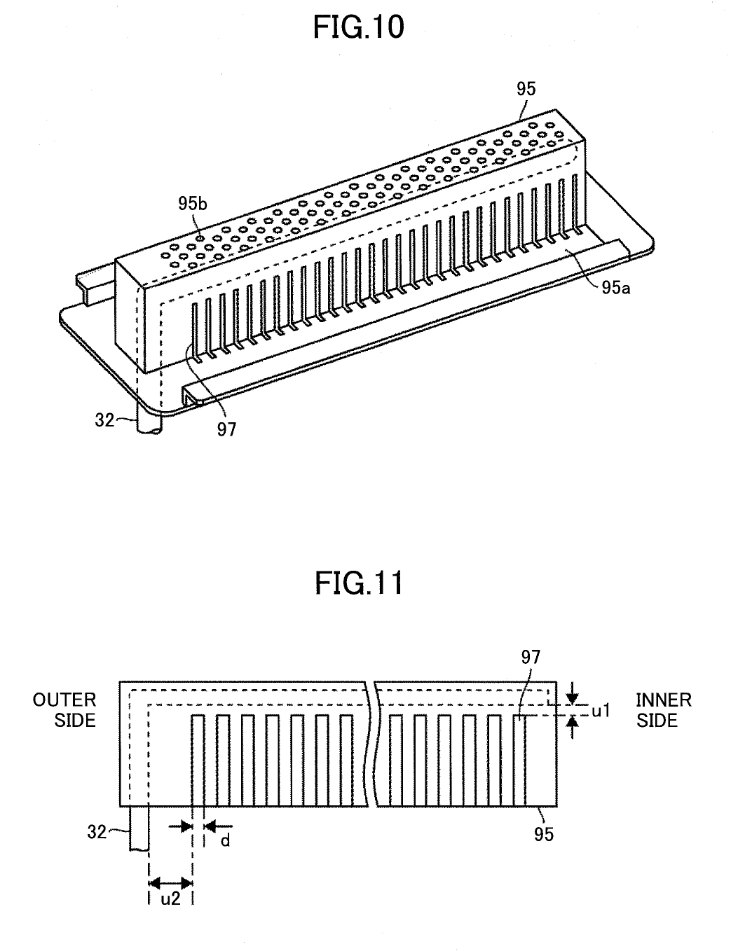

The slits 97 are formed such that they extend in a direction (in this example, vertical direction) that is orthogonal to (or intersects with) an extending direction in which the antenna 83 extends, and are arranged along the length direction of the antenna 83. In this example, the extending direction of the antenna 83 is the same as the length direction of the antenna 83. However, depending on the configuration of the antenna 83, the extending direction of the antenna 83 may be different from the length direction of the antenna 83. An opening size d (see FIG. 11) in the horizontal direction of each slit 97 may be set at about 1 to 5 mm. In this example, it is assumed that the opening size d is 2 mm. This is based on an assumption that the high-frequency power supply 85 with a frequency of 13.56 MHz is connected to the antenna 83. In this case, the wavelength corresponding to a frequency of 13.56 MHz is 22 m, and the opening size d of the slit 97 is set at a value that is about 1/10000 or less of the wavelength. An interval (or space) between adjacent slits 97 may be set at about 1 to 5 mm. In this example, it is assumed that the interval is 2 mm.

Each slit 97 may extend from a position on a vertical surface of the Faraday shield 95 to a position that is on the horizontal surface 95a and close to the vertical surface. That is, the slit 97 may be shaped like a character “L” when seen from the outer side toward the center side of the rotary table 2. The metal plate of the Faraday shield 95 is present at both ends in the length direction of the slit 97 to prevent the electric field from leaking into the upper chamber 21 via the ends of the slit 97. In other words, the slits 97 are located away from the edges of the Faraday shield 95. Reference number 95b in FIG. 9 indicates confirmation windows (openings) formed in the ceiling (or upper surface) of the Faraday shield 95. The confirmation windows 95b are used to confirm whether plasma is generated (i.e., emitting light) in the upper chamber 201. The confirmation windows 95b are formed, for example, by punching metal to block the electric field component. The size (e.g., diameter) of each confirmation window 95b is set at a value that is substantially the same as the opening size d of the slit 97.

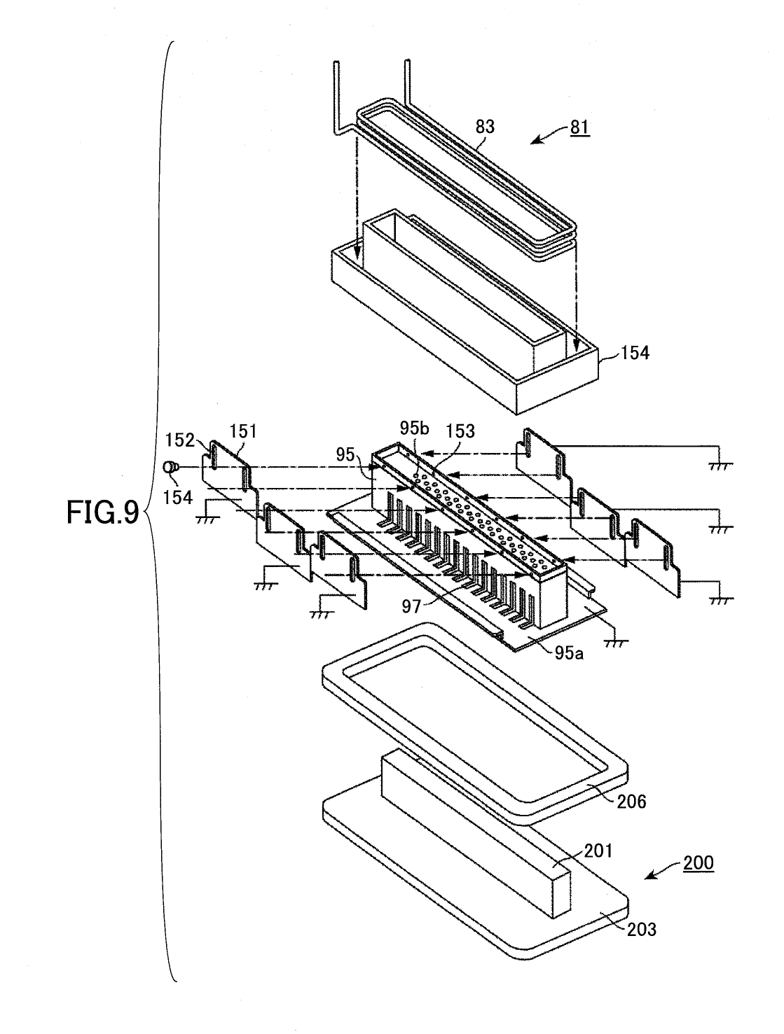

As illustrated by FIGS. 9 and 10, slits 97 are not formed in side surfaces of the Faraday shield 95 that face the center side and the outer side of the rotary table 2. Accordingly, these side surfaces of the Faraday shield 95 block both the electric field component and the magnetic field component generated around the antenna 83. Here, an inner part of the upper chamber 201, which is closer to the center side of the rotary table 2, is surrounded by the antenna 83 on three sides: a side surface (upstream side surface) facing upstream in the rotational direction of the rotary table 2, a side surface (downstream side surface) facing downstream in the rotational direction of the rotary table 2, and a side surface (inner side surface) facing the center side of the rotary table 2. Similarly, an outer part of the upper chamber 201, which is closer to the outer side of the rotary table 2, is surrounded by the antenna 83 on three sides: a side surface facing upstream in the rotational direction of the rotary table 2, a side surface facing downstream in the rotational direction of the rotary table 2, and a side surface (outer side surface) facing the outer side of the rotary table 2.

On the other hand, a middle part of the upper chamber 201, which is between the inner part and the outer part, is sandwiched by straight parts of the antenna 83 that extend along the radial direction of the rotary table 2. That is, the middle part of the upper chamber 201 is surrounded by the antenna 83 only on two sides: a side surface facing upstream in the rotational direction of the rotary table 2 and a side surface facing downstream in the rotational direction of the rotary table 2. Accordingly, in a strip-shaped area surrounded by the antenna 83 (or where the upper chamber 201 is placed) in plan view, the amount of magnetic field component is greater in the end parts of the strip-shaped area than in the middle part of the strip-shaped area. For this reason, the slits 97 are not formed in the side surfaces of the Faraday shield 95 that face the center side and the outer side of the rotary table 2 to make the plasma density (or the amount of magnetic field component) uniform in the radial direction of the rotary table 2. Alternatively, the slits 97 may be formed in all of the four side surfaces of the Faraday shield 95, and the density of the silts 97 in the inner and outer side surfaces may be made smaller than the density of the silts 97 in the upstream and downstream side surfaces.

As illustrated by FIG. 11, the slits 97 are arranged and positioned such that both the electric field component and the magnetic field component do not reach the primary plasma generating gas nozzle 32. The gas ejection holes 33 are formed in the lower surface of the primary plasma generating gas nozzle 32 along the length direction of the primary plasma generating gas nozzle 32. The diameter of the gas ejection holes 33 is very small and is, for example, about 0.3 mm to 1 mm. If plasma is generated at the primary plasma generating gas nozzle 32, parts of the primary plasma generating gas nozzle 32 around the gas ejection holes 33 may be broken.

For this reason, the slits 97 are formed in parts of the side surfaces of the Faraday shield 95 where the primary plasma generating gas nozzle 32 does not exist. More specifically, as in FIG. 11 that illustrates the upper chamber 201 seen from the upstream in the rotational direction of the rotary table 2, a gap u1 of, for example, about −5 mm to 20 mm may be provided between the upper end of each slit 97 and the lowermost surface of a part of the primary plasma generating gas nozzle 32 that extends horizontally. The lowermost surface of the primary plasma generating gas nozzle 32 may be positioned lower than the upper end of the slit 97. Also, a gap u2 of, for example, about 0 mm to 20 mm may be provided between the outermost slit 97, which is closest to the outer side of the rotary table 2, and a vertical part of the primary plasma generating gas nozzle 32. Thus, the slits 97 are arranged such that the antenna 83 cannot be seen through the slits 97 from the side of the primary plasma generating gas nozzle 32.

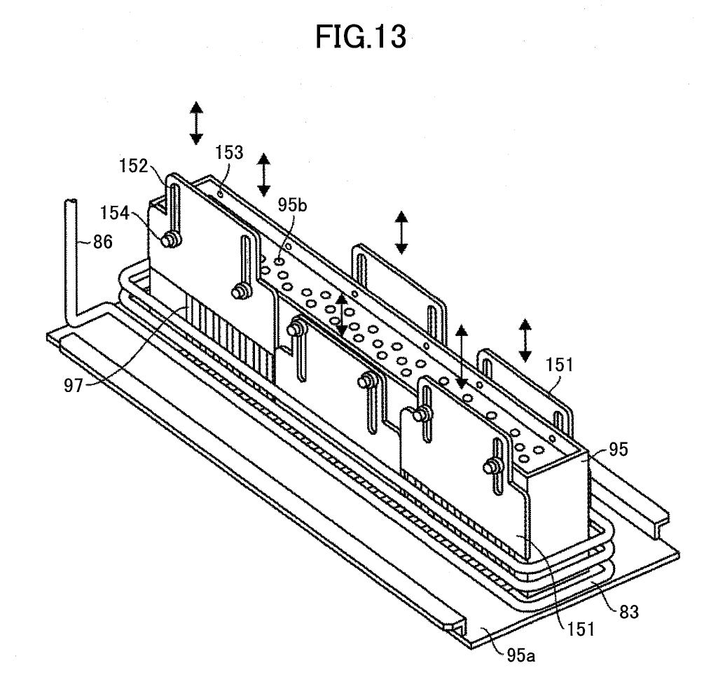

Shutters 151 or adjustment parts made of metal plates of, for example, copper are provided between the Faraday shield 95 and the antenna 83. The shutters 151 are used to open and close the slits 97. The primary plasma generating gas nozzle 32, the antenna 83, the Faraday shield 95, and the shutters 151 constitute an assembly. As described above, the slits 97 are provided to allow the magnetic field component to pass through the Faraday shield 95. The shutters 151 are used to open and close the slits 97 and to adjust the opening area of the slits 97. In other words, the shutters 151 adjust the amount of magnetic field component that passes through the Faraday shield 95. In the example of FIGS. 9 and 13, three shutters 151 are arranged along the radial direction of the rotary table 2 (i.e., between the center side and the outer side of the rotary table 2) on each of the upstream side surface and the downstream side surface of the Faraday shield 95 to adjust the plasma density in the radial direction of the rotary table 2.

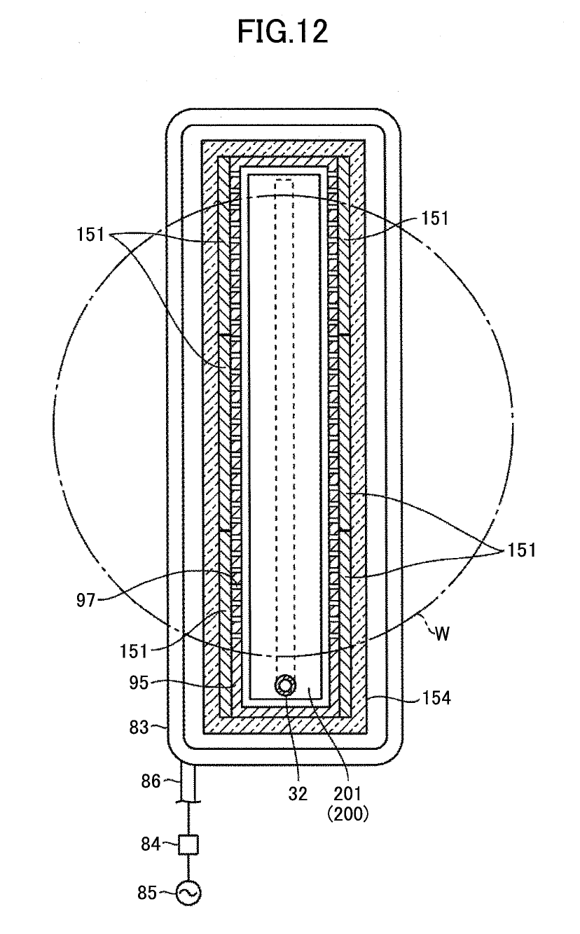

More specifically, the shutters 151 have substantially the same plate-like shape and disposed along the side surfaces of the Faraday shield 95 where the slits 97 are formed. Each of the shutters 151 is disposed to face an area where, for example, 30 slits 97 are formed. As illustrated by FIG. 12, in plan view, each shutter 151 may have a length that is greater than or equal to one third of the diameter of the wafer W that is below the upper chamber 201. In FIG. 12, the outer edge of the wafer W is indicated by a dashed-dotted line.

Long holes 152, which extend vertically, are formed in the upper part of the shutter 151. For example, two long holes 152, which are apart from each other in the radial direction of the rotary table 2, are formed in each shutter 151. Volt holes 153 corresponding to the long holes 152 are formed in the upstream and downstream side surfaces of the Faraday shield 95 at positions near the upper ends of the upstream and downstream side surfaces. As illustrated by FIGS. 13 and 17 through 19, the vertical position (height) of the shutter 151 is adjustable and can be fixed by fixing the shutter 151 to the Faraday shield 95 using bolts 154. Thus, the amount of magnetic field component that reaches the inside of the upper chamber 201 can be adjusted by adjusting the vertical positions of the shutters 151 and thereby adjusting the opening area of the slits 97.

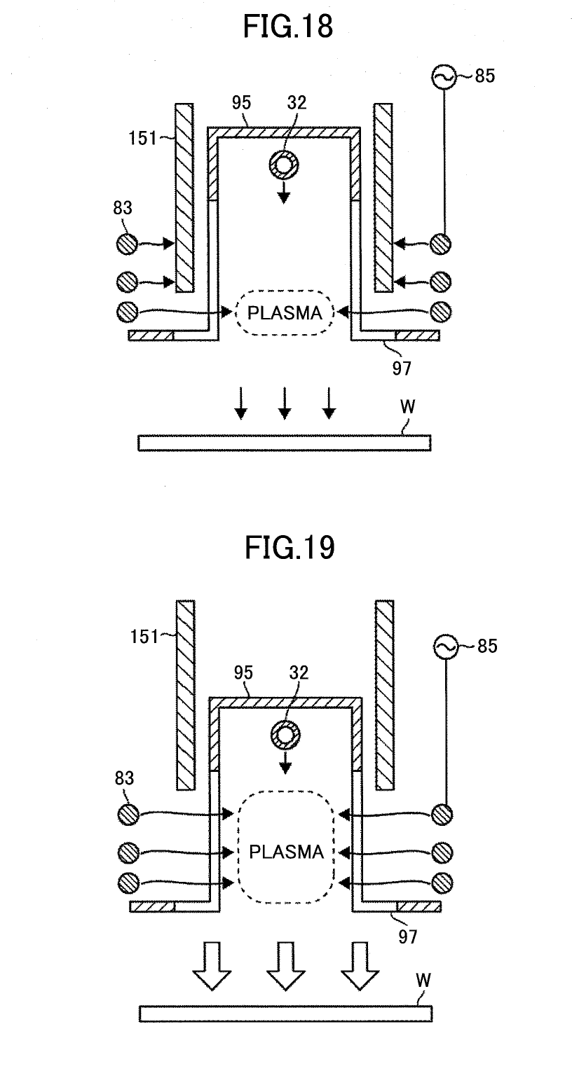

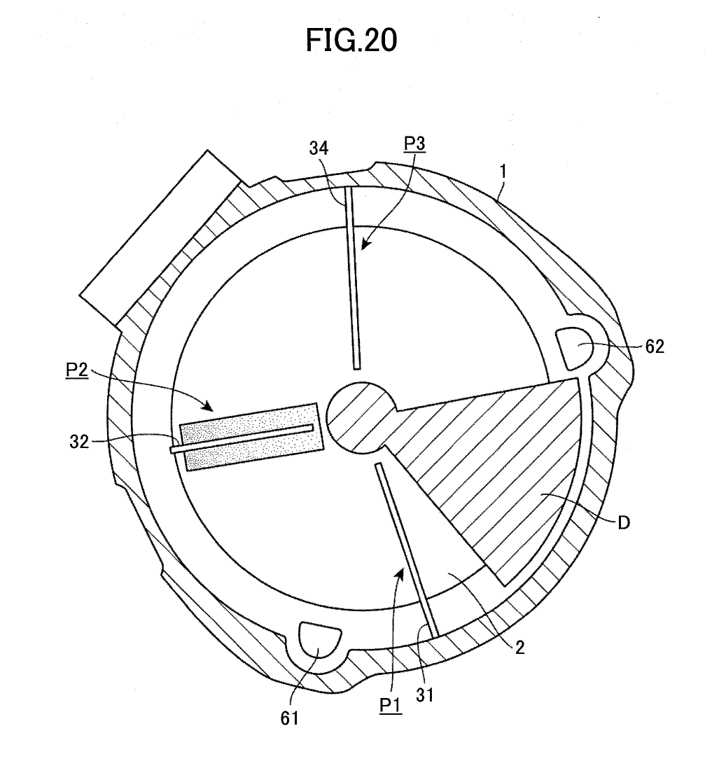

For example, each shutter 151 may be placed in one of a vertical position that allows three lines of the antenna 83 (which is wound around the vertical axis three times) to be seen from the inside of the upper chamber 201, a vertical position that allows two lines of the antenna 83 to be seen, a vertical position that allows one line of the antenna 83 to be seen, and a vertical position that allows no line of the antenna 83 to be seen. In the example of FIG. 17, a right shutter 151 of right and left shutters 151 that face each other across the upper chamber 201 is placed in a vertical position that allows three lines of the antenna 83 to be seen from the inside of the upper chamber 201. On the other hand, the left shutter 151 is placed in a vertical position to cover the slits 97 on the left side surface of the Faraday shield 95. In the example of FIG. 18, both of the right and left shutters 151 are placed in a vertical position that allows one line of the antenna 83 to be seen from the inside of the upper chamber 201. In the example of FIG. 19, both of the right and left shutters 151 are placed in a vertical position that allows three lines of the antenna 83 to be seen from the inside of the upper chamber 201. Thus, with the shutters 151 that are provided along the radial direction of the rotary table 2 and individually adjustable in the vertical (height) direction, it is possible to adjust the amount of magnetic field component in the radial direction of the rotary table 2. In FIG. 9, reference number 164 indicates an insulator, which is made of, for example, quartz, for insulating the antenna 83 from the Faraday shield 95 and the shutters 151.

As illustrated by FIG. 5, a lifting mechanism 162 is connected via a lifting shaft 161 to each shutter 151. A control unit (described later) controls the lifting mechanism 162 to adjust the vertical position of each shutter 151 according to, for example, a process recipe to be applied to the wafer W. Because the shutter 151 is moved up and down by the lifting mechanism 162 along the long holes 152, the long holes 152 may be referred to as a “guide mechanism” that guides the upward and downward movements of the shutter 151. The lifting mechanism 162 may be configured to maintain the vertical position of the shutter 151. In this case, the bolts 154 may be omitted. For brevity, only one set of the lifting shaft 161 and the lifting mechanism 162 is illustrated in FIG. 5, and the lifting shaft 161 and the lifting mechanism 162 are omitted in other figures. Also for brevity, only one bolt 154 is illustrated in FIG. 9, and the Faraday shield 95 and the shutters 151 are omitted in FIG. 1.

Next, the first process gas nozzle 31 is described. As illustrated by FIGS. 2 and 3, a nozzle cover 230, which has a configuration similar to the fin 221, is provided above the first process gas nozzle 31. The nozzle cover 230 includes a box-shaped part with an opening on the lower side to house the first process gas nozzle 31, and horizontal parts that extend horizontally from an upstream lower end and a downstream lower end of the box-shaped part in the rotational direction of the rotary table 2. The width of the nozzle cover 230 increases in a direction from the center side to the outer side of the rotary table 2. Accordingly, the nozzle cover 230 is shaped like a fan in plan view. The nozzle cover 230 causes the first process gas to flow along the wafer W and prevents the separation gas from flowing near the wafer W, i.e., causes the separation gas to flow near the top plate 11 of the vacuum chamber 1. The nozzle cover 230 is supported by a protrusion 5 and a cover part 7a described later.

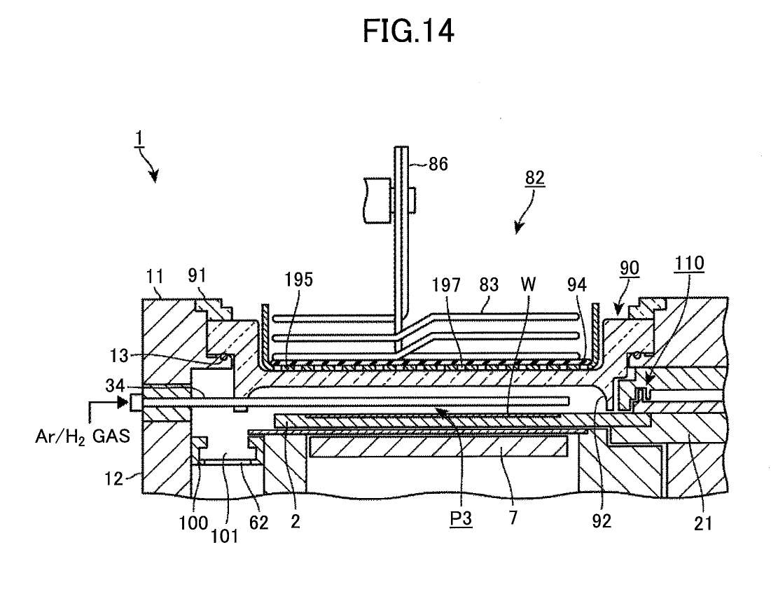

Next, the secondary plasma generator 82 is described. As illustrated by FIGS. 14 through 16, the secondary plasma generator 82 is provided above the secondary plasma generating gas nozzle 34. The secondary plasma generator 82 converts a reforming gas ejected from the secondary plasma generating gas nozzle 34 into plasma. Similarly to the primary plasma generator 81, the secondary plasma generator 82 includes an antenna 83 that is implemented by winding metal wire three times around a vertical axis like a coil. In plan view, the secondary plasma generator 82 (or the antenna 83) is disposed to surround a strip-shaped area that extends in the radial direction of the rotary table 2 and extends across the diameter of the wafer W on the rotary table 2. The antenna 83 is connected via a matching box 84 to a high-frequency power supply 85 with, for example, a frequency of 13.56 MHz and an output power of 5000 W. The antenna 83 is hermetically separated from the inside of the vacuum chamber 1.

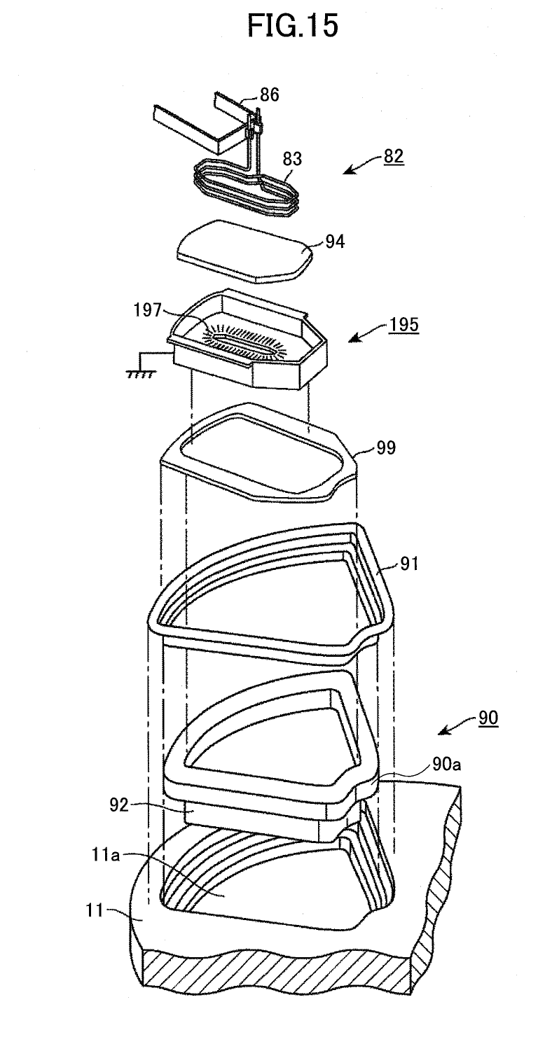

As illustrated by FIGS. 14 and 15, an opening 11a shaped like a fan in plan view is formed in a part of the top plate 11 above the secondary plasma generating gas nozzle 34. A housing 90 composed of a dielectric material such as quartz is provided in the opening 11a. As illustrated by FIG. 17, the upper rim of the housing 90 extends horizontally as a flange 90a and the flange 90a engages the top plate 11. The center part of the housing 90 in plan view is recessed toward the inside of the vacuum chamber 1, and the antenna 83 is placed in the recessed part of the housing 90.

The housing 90 is placed in the opening 11a, the flange 90a is pressed downward by a pressing part 91 shaped like a frame along the outer edge of the opening 11a, and the pressing part 91 is fixed to the top plate 11 with, for example, bolts to hermetically seal the vacuum chamber 1.

A protrusion 92 is formed on the lower surface of the housing 90. The protrusion 92 extends vertically toward the rotary table 2 and surrounds a process area P3 below the housing 90. The secondary plasma generating gas nozzle 34 is placed in a space surrounded by the inner circumferential surface of the protrusion 92, the lower surface of the housing 90, and the upper surface of the rotary table 2.

A Faraday shield 195, which is grounded, is provided between the housing 90 and the antenna 83. The Faraday shield 195 is composed of a plate made of a conductive material such as copper and has a shape that substantially fits the internal shape of the housing 90. Slits 197 are formed in a part of the Faraday shield 195 below the antenna 83. The slits 197 extend in directions that are orthogonal to the direction in which the antenna 83 is wound, and are arranged to form a circle below the antenna 83. The dimensions of the slits 197 may be determined in a manner similar to those of the slits 97. The slits 197 are formed at positions away from the outer edge of the Faraday shield 195 (i.e., in an area close to the center of the Faraday shield 195) such that no opening is formed in the periphery of the Faraday shield 195. An opening is formed in an area of the Faraday shield 195 surrounded by the antenna 83 in plan view. The opening is used to check whether plasma is emitting light. In FIG. 14, reference number 94 indicates an insulator for insulating the antenna 83 from the Faraday shield 195. In FIG. 2, the slits 197 are omitted, but an area where the slits 197 are formed is indicated by a dashed-dotted line.

Components of the vacuum chamber 1 are described below. As illustrated by FIGS. 1 and 3, a side ring 100, which is a cover, is provided along the outer circumference of the rotary table 2 and slightly below the rotary table 2. First and second evacuation ports 61 and 62, which are apart from each other in the circumferential direction, are formed in the upper surface of the side ring 100. More specifically, the first and second evacuation ports 61 and 62 are formed in the side ring 100 at positions that correspond to evacuation ports formed in the bottom surface of the vacuum chamber 1. The first evacuation port 61 is positioned between the first process gas nozzle 31 and the separation area D located downstream of the first process gas nozzle 31 in the rotational direction of the rotary table 2, and is closer to the separation area D than to the first process gas nozzle 31. The second evacuation port 62 is positioned between the secondary plasma generator 82 and the separation area D located downstream of the secondary plasma generator 82 in the rotational direction of the rotary table 2, and is closer to the separation area D than to the secondary plasma generator 82. The first evacuation port 61 is configured to discharge the Si-containing gas and the separation gas, and the second evacuation port 62 is configured to discharge the ammonia gas, the reforming gas, and the separation gas. As illustrated by FIG. 1, each of the first evacuation port 61 and the second evacuation port 62 is connected via an evacuation pipe 63 with a pressure controller 65 such as a butterfly valve to a vacuum pump 64 that is an evacuation mechanism.

Here, gases that flow from the upstream in the rotational direction of the rotary table 2 to the process areas P2 and P3 and then flow toward the first and second evacuation ports 61 and 62 are limited by the housing 90 and the plasma generating chamber 200 that extend from the center area C toward the outer wall of the vacuum chamber 1. For this reason, gas flow paths 101, which are grooves for allowing the gases to flow, are formed in the upper surface of the side ring 100 at positions closer to the outer wall of the vacuum chamber 1 than the outer ends of the housing 90 and the plasma generating chamber 200.

As illustrated by FIG. 2, a protrusion 5 with a substantially ring shape is formed on a center part of the lower surface of the top plate 11. The protrusion 5 is connected with the inner ends (that face the center area C) of the raised parts 4, or the protrusion 5 and the raised parts 4 are formed as a monolithic part. The height of the lower surface of the protrusion 5 is substantially the same as the height of the lower surfaces (the ceiling surfaces 44) of the raised parts 4. A labyrinth structure 110 is formed above the core 21 at a position closer to the center of rotation of the rotary table 2. The labyrinth structure 110 prevents the Si-containing gas and the ammonia gas from mixing with each other in the center area C. As illustrated by FIG. 1, the labyrinth structure 110 is formed by arranging a ring-shaped first wall 111 and a ring-shaped second wall 112 in the radial direction of the rotary table 2. The first wall 111 extends vertically from the rotary table 2 toward the top plate 11, and the second wall 112 extends vertically from the top plate 11 toward the rotary table 2.

As illustrated by FIG. 1, a heater unit 7, which is a heating mechanism, is provided in a space between the rotary table 2 and the bottom 14 of the vacuum chamber 1. The heater unit 7 heats, via the rotary table 2, the wafers W on the rotary table 2 to, for example, 300° C. In FIG. 1, reference number 71a indicates a cover part disposed laterally to the heater unit 7, and reference number 7a indicates a cover part disposed above the heater unit 7. Purge gas supplying tubes 73 are provided in the bottom 14 of the vacuum chamber 1 below the heater unit 7. The purge gas supplying tubes 73 are arranged in the circumferential direction and used to purge the space where the heater unit 7 is placed.

As illustrated by FIGS. 2 and 3, a transfer opening 15 is formed in the side wall of the vacuum chamber 1. The transfer opening 15 is used to transfer the wafer W between an external transfer arm 10 and the rotary table 2. A gate valve G is provided to hermetically open and close the transfer opening 15. A camera unit 10a is provided above the top plate 11 in an area where the transfer arm 10 is moved into and out of the vacuum chamber 1. The camera unit 10a is used to detect the outer edge (or rim) of the wafer W.

The wafer W is transferred between the recess 24 of the rotary table 2 and the transfer arm 10 at a transfer position facing the transfer opening 15. Lifting pins (not shown) and a lifting mechanism (not shown) for driving the lifting pins is provided below the rotary table 2 at a position corresponding to the transfer position. The lifting pins pass through the recess 24 and lift the wafer W.

The plasma process apparatus may also include a control unit 120 that is a computer or a processor for controlling the entire operations of the plasma process apparatus. The control unit 120 includes a memory that stores data and a program(s). The data includes process recipes (types) to be performed on the wafer W and positions of the shutters 151 associated with the process recipes. As described above, the plasma density distribution in the vacuum chamber 1 varies depending on a process pressure, a gas flow rate, and types of gases used in the vacuum chamber 1. Accordingly, the optimum positions of the shutters 151, with which the degree of plasma processing becomes uniform across the surface of the wafer W, also vary depending on the process recipes. For this reason, the memory stores data that associates the process recipes with positions of the shutters 151.

The program causes the control unit 120 to read, from the data, the positions of the shutters 151 corresponding to a recipe selected for the wafer W, and to send control signals to components including the lifting mechanism 162 of the plasma process apparatus to perform a film deposition process and a reforming process. The program may include steps for causing the plasma process apparatus to perform processes as described below. The program may be stored in a storage unit 121 that is a storage medium such as a hard disk, a compact disk, a magneto-optical disk, a memory card, or a flexible disk, and installed from the storage unit 121 into the control unit 120.

Next, exemplary operations of the plasma process apparatus according to the present embodiment are described. First, the vertical positions of the shutters 151 are adjusted. As described above, when the rotary table 2 rotates about a vertical axis, the wafers W on the rotary table 2 are rotated around the center of rotation of the rotary table 2. Therefore, the angular speed of an inner part of each wafer W closer to the center of rotation of the rotary table 2 is, for example, three times lower than the angular speed of an outer part of the wafer W closer to the outer end of the rotary table 2. As a result, plasma irradiation time for the inner part of the wafer W becomes longer than plasma irradiation time for the outer part of the wafer W. According to the present embodiment, to make the degree (level or strength) of plasma processing uniform in the radial direction of the rotary table 2, the vertical positions of the shutters 151 are adjusted. In the present embodiment, it is assumed that three (or three pairs) of shutters 151 are arranged in the radial direction of the rotary table 2, and the antenna 83 is wound around the vertical axis three times. In the descriptions below, each wind of the antenna 83 is referred to as a “line” and it is assumed that three lines of the antenna 83 are present around the upper chamber 201. For example, as illustrated by FIG. 18, the vertical position of an inner shutter(s) 151 of the shutters 151 closest to the center of rotation of the rotary table 2 is adjusted such that one line of the antenna 83 is visible from the inside of the upper chamber 201. In other words, the vertical position of the inner shutter 151 is adjusted to face two lines of the antenna 83.

As illustrated by FIG. 19, the vertical position of an outer shutter(s) 151 of the shutters 151 closest to the outer end of the rotary table 2 is adjusted such that all three lines of the antenna 83 are visible from the inside of the upper chamber 201. Also, the vertical position of a middle shutter(s) 151 of the shutters 151 located in the middle in the radial direction of the rotary table 2 is adjusted such that two lines of the antenna 83 are visible from the inside of the upper chamber 201.

Next, the gate valve G is opened and while the rotary table 2 is being rotated intermittently, the wafers W (e.g., five wafers W) are placed by the transfer arm 10 on the rotary table 2 via the transfer opening 15. Here, it is assumed that a wiring embedding process has been performed on each wafer W by, for example, dry etching and/or chemical vapor deposition (CVD), and an electric wiring has been formed in each wafer W. Next, the gate valve G is closed, the vacuum chamber 1 is evacuated by the vacuum pump 64 and the pressure controller 65, and the wafers W are heated to 300° C. by the heater unit 7 while rotating the rotary table 2 clockwise.

A Si-containing gas is discharged from the process gas nozzle 31 at, for example, 300 sccm, and an ammonia gas is discharged from the primary plasma generating gas nozzle 32 at, for example, 100 sccm. Also, a mixed gas of an argon gas and a hydrogen gas is discharged from the secondary plasma generating gas nozzle 34 at, for example, 10000 sccm. Further, a separation gas is discharged from each of the separation gas nozzles 41 and 42 at, for example, 5000 sccm, and a nitrogen gas is discharged from each of the separation gas supplying tube 51 and the purge gas supplying tubes 72 and 73 at a predetermined flow rate. The pressure in the vacuum chamber 1 is adjusted by the pressure controller 65 at a predetermined process pressure of, for example, 400 to 500 Pa. In this example, it is assumed that the process pressure is set at 500 Pa. The plasma generators 81 and 82 supply a high-frequency power of, for example, 1500 W to the corresponding antennas 83.

At the plasma generator 81, an electric field and a magnetic field are generated around the antenna 83. The Faraday shield 95 provided between the antenna 83 and the upper chamber 201 prevents the electric field from entering into the upper chamber 201. On the other hand, the magnetic field generated around the antenna 83 enters the upper chamber 201 via the slits 97 formed in the Faraday shield 95. In the plasma generating chamber 200, the ammonia gas supplied from the primary plasma generating gas nozzle 32 into the upper chamber 201 is activated by the magnetic field formed by the antenna 83 and as a result, plasma including ammonia radicals is generated. Because the opening area of the slits 97 near the center side of the rotary table 2 is made smaller than that near the outer side of the rotary table 2, the density of the plasma in an inner part of the upper chamber 201 near the center side of the rotary table 2 is less than the density of the plasma in an outer part of the upper chamber 201 near the outer side of the rotary table 2.

The plasma flowing down toward the lower chamber 202 is limited or regulated by the partition plate 210 between the upper and lower chambers 201 and 202. As a result, the pressure of the plasma in the upper chamber 201 becomes slightly higher than the pressure of the plasma in other areas in the vacuum chamber 1. This high-pressure plasma flows down toward the wafer W through the discharge opening 211 formed in the partition plate 210. Because the pressure in the upper chamber 201 is greater than the pressure in other areas in the vacuum chamber 1, other gases such as the nitrogen gas do not enter the upper chamber 201. The plasma discharged from the lower end of the lower chamber 202 is caused by the fin 221 to flow in the rotational direction of the rotary table 2 across the radius of the rotary table 2, i.e., along the wafer W. Since the lifetime of the ammonia radicals is longer than the lifetime of the plasma of the argon gas, the activity of the ammonia radicals is maintained even when the ammonia radicals reach the wafer W.

In the housing 90, the electric field is blocked by the Faraday shield 195, and the magnetic field enters the vacuum chamber 1 through the slits 197. Accordingly, the reforming gas including the argon gas is converted by the magnetic field into plasma at a position below the housing 90. Since the lifetime of the plasma of the argon gas is shorter than the lifetime of the plasma of the ammonia gas, the plasma of the argon gas tends to be inactivated and return to the argon gas immediately. However, because the antenna 83 of the secondary plasma generator 82 is disposed near the wafer W on the rotary table 2, i.e., the plasma is generated in an area immediately above the wafer W, the plasma of the argon gas flowing toward the wafer W maintains its activity. The protrusion 92 formed around the lower surface of the housing 90 prevents gases and plasma from going out of an area below the housing 90. Therefore, the pressure of atmosphere in the area below the housing 90 becomes slightly higher than the pressure of atmosphere in other areas (e.g., an area where the transfer arm 10 moves in and out of the vacuum chamber 1) of the vacuum chamber 1. This in turn prevents gases from entering into the housing 90.

As the rotary table 2 is rotated, the Si-containing gas is adsorbed onto the surface of the wafer W in the first process area P1, and the components of the Si-containing gas adsorbed onto the wafer W are nitrided by the plasma of the ammonia gas in the second process area P2. As a result, one or more molecular layers of silicon nitride (Si—N), which is a thin-film component, are formed as a reaction product. Because the vertical positions of the shutters 151 are adjusted to make the degree of plasma processing uniform in the radial direction of the rotary table 2, the quality and thickness of the reaction product become uniform across the surface of the wafer W. Here, because of, for example, a residual radical in the Si-containing gas, the silicon nitride may include impurities such as chlorine (Cl) and organic matter.

When the rotary table 2 is rotated further, the plasma generated by the secondary plasma generator 82 touches the surface of the wafer W and the silicon nitride is reformed. For example, when the plasma hits the surface of the wafer W, the impurities are released from the silicon nitride as HCl or an organic gas, or the elements in the silicon nitride are rearranged and the density of the silicon nitride increases. The rotary table 2 is rotated repeatedly, and steps including absorption of the Si-containing gas onto the surface of the wafer W, nitriding of the components of the Si-containing gas adsorbed onto the surface of the wafer W, and plasma reformation of a reaction product are performed multiple times in this order. As a result, multiple layers of the reaction product, i.e., a thin film, is formed. Here, because the electric field is blocked in the primary plasma generator 81 and the secondary plasma generator 82, electric damage to the electric wiring structure formed in the wafer W is prevented.

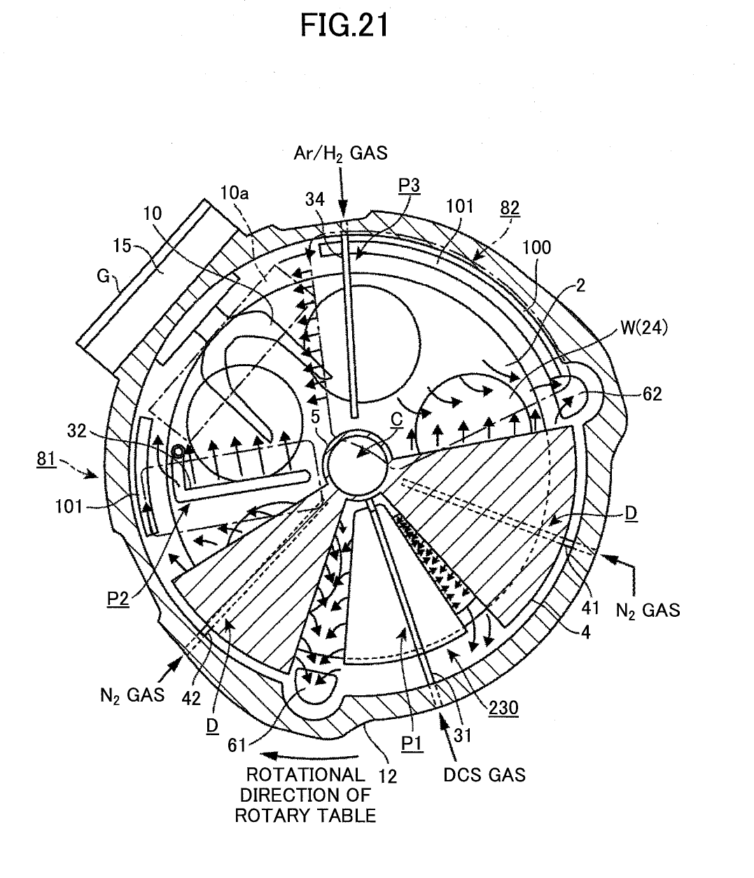

As described above, the separation areas D are formed between the process areas P1 and P2, in other words, on both sides of the process area P1 in the circumferential direction of the rotary table 2. As illustrated by FIG. 21, mixing of the Si-containing gas and the ammonia gas in the separation areas D is prevented, and the gases are caused to flow into the evacuation ports 61 and 62.

According to the above embodiment, plasma processing is performed on the wafer W using the antenna 83, and the Faraday shield 95 made of a conductive plate is provided to block the electric field in an electromagnetic field generated by the antenna 83. Also, the slits 97 are formed in the Faraday shield 95 to allow the magnetic field in the electromagnetic field to pass through. Further, the shutters 151 are provided between the antenna 83 and the Faraday shield 95 to adjust the opening area of at least one of the slits 97. This configuration makes it possible to adjust the plasma density in the radial direction of the rotary table 2, and thereby makes it possible to make the degree of plasma processing uniform across the surface of the wafer W being rotated by the rotary table 2.

Also, the above configuration eliminates the need to arrange multiple antennas, which are connected separately to different high-frequency power supplies, in the radial direction of the rotary table 2 to adjust the plasma density (or the amount of magnetic field) in the radial direction of the rotary table 2. This in turn makes it possible to reduce the production costs of the plasma process apparatus.

Also according to the above embodiment, for a plasma nitridation process to be performed on the wafer W, the upper chamber 201 is provided above the top plate 11 and the lower chamber 202 for guiding plasma to the wafer W on the rotary table 2 is provided below the upper chamber 202. This configuration makes it possible to place components such as the antenna 83 and the primary plasma generating gas nozzle 32 used for plasma processing in a region that is above and away from the rotary table 2. This in turn makes it possible to reduce an area occupied by the region and the components in the process areas P1 and P3 and the separation areas D when seen from the areas P1, P3, and D in the circumferential direction of the rotary table 2, and thereby makes it possible to reduce the size of the vacuum chamber 1 in plan view.

Because various components such as the nozzles 31, 34, 41, and 42 and the raised parts 4 are provided in the vacuum chamber 1, it is difficult to place the primary plasma generating gas nozzle 32 in the vacuum chamber 1. On the other hand, compared with the inside of the vacuum chamber 1, there is a large space above the top plate 11 of the vacuum chamber 1 and it is easy to place the primary plasma generating gas nozzle 32 and the upper chamber 201 above the top plate 11. Accordingly, this configuration makes it easier to secure a transfer area for the wafer W and a space for the camera unit 10a even in a small apparatus (the vacuum chamber 1).

Also, an ammonia gas is used as a gas to be converted into plasma in the upper chamber 201 disposed above the top plate 11. Because the lifetime of the plasma of the ammonia gas (i.e., the period of time for which the plasma is active) is longer than the lifetime of plasma of an argon gas as described above, it is possible to properly perform plasma processing on the wafer W even when the upper chamber 201 and the wafer W are apart from each other.

Also, because the discharge opening 211 is formed in the plasma generating chamber 200, it is possible to make the pressure in the upper chamber 201 higher than other areas (e.g., an area where the transfer arm 10 moves in and out of the vacuum chamber 1) in the vacuum chamber 1. This in turn makes it possible to set the pressure in the upper chamber 201 separately from the pressure in the vacuum chamber 1. That is, the pressure in the upper chamber 201 can be adjusted according to a process recipe or a type of wafer W. For example, when a hole or a groove with a large aspect ratio (or a large depth) is formed in the surface of the wafer W, the pressure in the upper chamber 201 may be set at a value that is about 200 Pa greater than the pressure in other areas of the vacuum chamber 1 so that a reaction product with high coverage can be formed on the wafer W. The above configuration also prevents the nitrogen gas from entering the upper chamber 201, and thereby prevents an adverse effect caused when the nitrogen gas is converted into plasma.

Also, the fin 221 is provided on both sides of the plasma generating chamber 200 (the lower chamber 202) in the circumferential direction of the rotary table 2 such that the fine 221 comes close to the wafer W on the rotary table 2. The outer rim of the fin 221 is bent to extend downward. The fin 221 makes it possible to increase the period of time for which the wafer W is in contact with the plasma of the ammonia gas.

The plasma generating chamber 200 has a long flat shape (or a strip-like shape) in plan view that extends along the radial direction of the rotary table 2. This configuration makes it possible to reduce the size of the plasma generating chamber 200 in the circumferential direction of the rotary table 200.

The Faraday shields 95 and 195 are provided between the corresponding antennas 83 and the wafer 83 to block electric fields generated by the antennas 83. This makes it possible to reduce electric damage caused by plasma to an electric wiring structure in the wafer W. Also according to the above embodiment, two plasma generators 81 and 82 are provided to perform different types of plasma processes. This configuration makes it possible to combine different types of plasma processes such as a plasma nitridation process on a Si-containing gas adsorbed onto the surface of the wafer W and a plasma reforming process on a reaction produce, and thereby makes it possible to produce an apparatus that can flexibly perform plasma processes.

The antennas 83 of the primary plasma generator 81 and the secondary plasma generator 82 are disposed outside of the vacuum chamber 1. This makes it easier to maintain the primary plasma generator 81 and the secondary plasma generator 82.

In the above example, it is assumed that each pair of the shutters 151 (upstream and downstream shutters 151) on the upstream side and the downstream side of the upper chamber 201 in the rotational direction of the rotary table 2 are placed at the same vertical position. However, each pair of the shutters 151 may be placed at different vertical positions. For example, the upstream shutter 151 of the two shutters 151 near the center side of the rotary table 2 may be placed at a vertical position as illustrated in FIG. 18, and the downstream shutter 151 of the two shutters 151 may be set at a vertical position as illustrated in FIG. 19. By separately setting the vertical positions of each pair of shutters 151 on the right and left of the upper chamber 201, it is possible to more finely adjust the amount of magnetic field that enters the upper chamber 201.

In the above example, three pairs of shutters 151 are arranged in the radial direction of the rotary table 2. However, any number of pairs of shutters 151 may be provided along the radial direction of the rotary table 2. For example, one pair of shutters 151 may be provided on the side surfaces of an inner part of the upper chamber 201 near the center side of the rotary table 2 to adjust the plasma density near the center side of the rotary table 2. As another example, the shutters 151 may be provided only on one of the right side (upstream side surface) and the left side (downstream side surface) of the upper chamber 201. Each shutter 151 may have an area that is sufficient to cover at least one slit 97, i.e., to adjust the opening area of at least one slit 97.

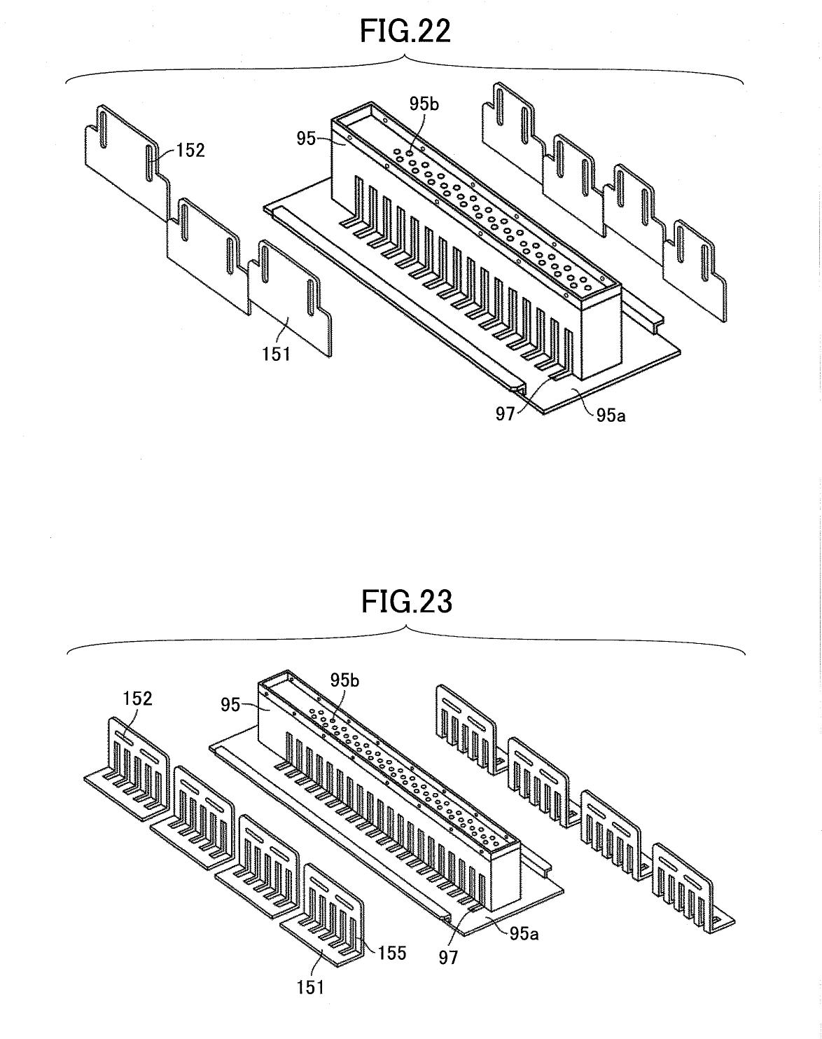

Different numbers of shutters 151 may be provided on the right side and the left side of the upper chamber 201. In the example of FIG. 22, four shutters 151 are provided on the right side of the upper chamber 201 and three shutters 151 are provided on the left side of the upper chamber 201. Accordingly, the number of slits 97 whose opening area can be adjusted by the four shutters 151 on the right side is different from the number of slits 97 whose opening area can be adjusted by the three shutters 151 on the left side (28 slits by the right shutters 151, and 21 slits by the left shutters 151).

By providing different numbers of shutters 151 on the right and left sides of the upper chamber 201, it is possible to more finely adjust the amount of magnetic field that enters the upper chamber 201. For example, the amount of magnetic field entering the upper chamber 201 (or the density distribution of plasma in the radial direction of the rotary table 2) is roughly adjusted by using the three shutters 151 on the left side of the upper chamber 201. Then, the amount of magnetic field entering the upper chamber 201 is finely adjusted by using the four shutters 151 on the right side of the upper chamber 201. Thus, the configuration of FIG. 22 makes it possible to adjust the density of plasma in smaller steps. The number of shutters 151 provided on each side of the upper chamber 201 may be determined freely. For example, six shutters 151 may be provided on the right side, and three shutters may be provided on the left side. Also, it is not necessary to provide the shutters 151 for all of the slits 97. In other words, no shutter 151 may be provided for some of the slits 97. Also, different numbers of slits 97 may be provided on the right and left sides of the upper chamber 201.

In the above embodiment, the shutters 151 are configured to be moved vertically. Alternatively, the shutters 151 may be configured to be moved horizontally between the center side and the outer side of the rotary table 2. FIG. 23 illustrates an example of shutters 151 configured to be moved horizontally. In FIG. 23, the long holes 152 are formed to extend horizontally. Also, multiple openings 155 that extend vertically are formed in each shutter 151. The openings 155 are configured to correspond to the slits 97 of the Faraday shield 95. More specifically, the openings 155 have the same opening size d as that of the slits 97, and the interval between the openings 155 is also the same as the interval between the slits 97.

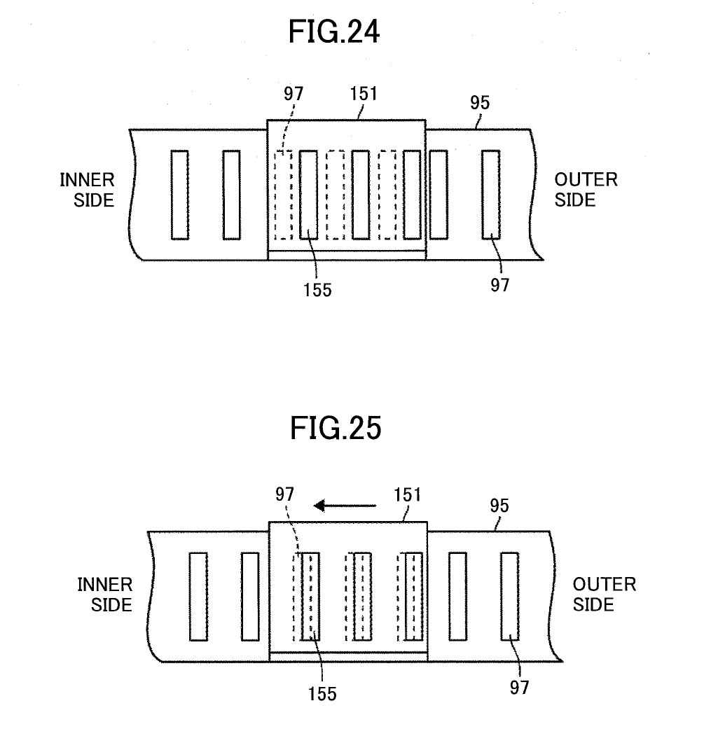

As illustrated by FIG. 24, when the shutter 151 is positioned such that the openings 155 of the shutter 151 do not overlap the slits 97 of the Faraday shield 95, i.e., each opening 155 is positioned between adjacent slits 97, the magnetic field component is blocked. On the other hand, as illustrated by FIG. 25, as the shutter 151 is slid toward the center side of the rotary table 2, an area where each opening 155 and each slit 97 overlap each other gradually increases. Accordingly, the slits 97 are opened by adjusting the position of the shutter 151 such that the slits 97 and the openings 155 completely overlap each other. Thus, it is possible to adjust the amount of magnetic field entering the upper chamber 201 by moving the shutters 151 horizontally.

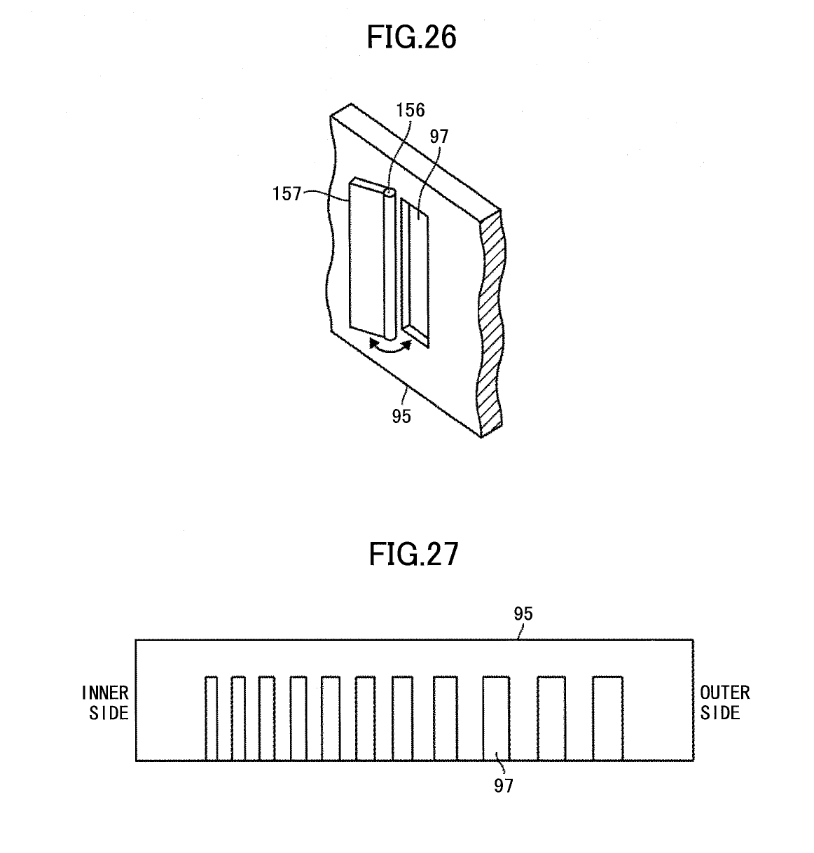

Also, as illustrated by FIG. 26, a metal plate 157 may be provided for each slit 97 to open and close the slit 97. The metal plate 157 is configured to rotate or swing around a rotational shaft 156 that is rotatable around the vertical axis and provided on the outer surface of the Faraday shield 95 between adjacent slits 97. With this configuration, it is possible to adjust the amount of magnetic field entering the upper chamber 201 by rotating the rotational shaft 156 to cause the metal plate 157 to swing between a position where the metal plate 157 covers the slit 97 and a position where the metal plate 157 is placed between the slits 97.

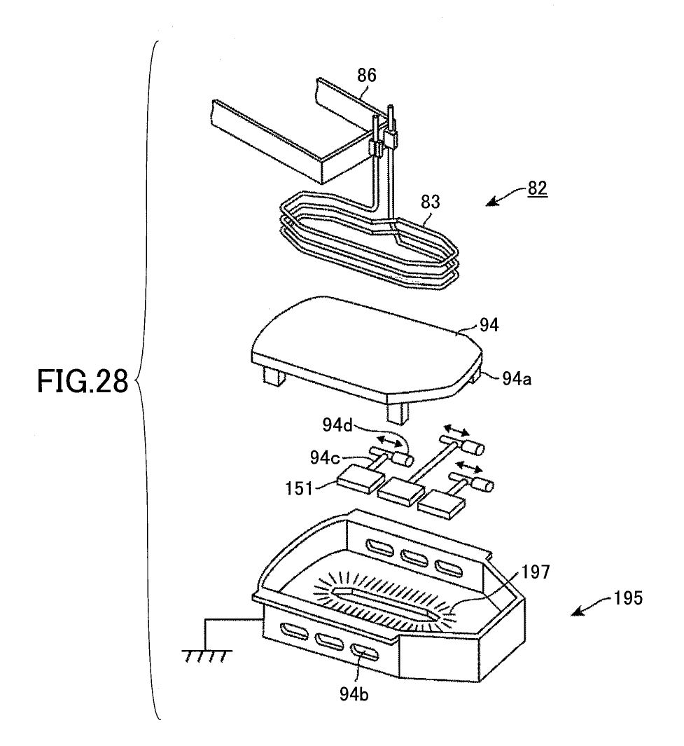

In the above example, it is assumed that the slits 97 of the Faraday shield 95 have the same size (or dimensions). However, slits 97 with different sizes may be formed in the Faraday shield 95. When it is expected that the degree of plasma processing is greater in an inner area near the center side of the rotary table 2 than in an outer area near the outer side of the rotary table 2, the opening size d of slits 97 in the inner area may be made smaller than the opening size of slits 97 in the outer area as illustrated by FIG. 27. In the example of FIG. 27, the opening size d of the slits 97 is gradually increased from the center side to the outer side of the rotary table 2. The slits 97 with different opening sizes d may be combined with the shutters 151 for adjusting the amount of magnetic field entering the upper chamber 201. Such a configuration makes it possible to more uniformly perform plasma processing on the wafer W. Also, instead of changing the opening size d of the slits 97, different numbers of slits 97 may be formed in an area near the center side of the rotational table 2 and an area near the outer side of the rotational table 2.

In the above example, the shutters 151 are provided around the plasma generating chamber 200. The shutters 151 may also be provided above the housing 90. FIG. 28 illustrates an exemplary configuration where the shutters 151 are provided above the housing 90. In FIG. 28, supports 94a for supporting the insulator 94 and thereby providing a space between the insulator 94 and the Faraday shield 195 are provided, for example, at four corners on the lower surface of the insulator 94. Long holes 94b (three in this example) are formed in each of upstream and downstream side surfaces (facing upstream and downstream in the rotational direction of the rotary table 2) of the Faraday shield 195. The long holes 94b extend horizontally and are apart from each other in the radial direction (from the center side to the outer side) of the rotary table 2.

Ends of drive shafts 94c, which extend horizontally in the tangential direction of the outer circumference of the rotary table 2, are inserted through the corresponding long holes 94b into the Faraday shield 195. The drive shafts 94c are movable forward and backward by driving parts 94d. Shutters 151 shaped like a plate and extending horizontally are provided above the slits 197 and connected to the ends of the corresponding drive shafts 94c. With this configuration, the amount of magnetic field entering the vacuum chamber 1 can be adjusted by moving the shutters 151 forward and backward via the drive shafts 94c. In FIG. 28, for illustration purposes, the drive shafts 94c, the driving parts 94d, and the shutters 151 are detached from the Faraday shield 195. Also in FIG. 28, the drive shafts 94c, the driving parts 94d, and the shutters 151 on the upstream side in the rotational direction of the rotary table 2 are omitted for brevity.

In the above embodiment, it is assumed that the Faraday shield 95 is grounded, and the shutters 151 that are in contact with the Faraday shield 95 are also grounded. However, the Faraday shield 95 and the shutters 151 may be separately grounded. Also, each of metal parts such as the Faraday shield 95 and the shutters 151 may be in an electrically floating state. That is, when there is no risk of causing electrostatic induction from the outer surface of a metal part to surrounding conductors (e.g., components constituting a vacuum transfer chamber or a load lock chamber (not shown) adjacent to the vacuum chamber 1, or another process apparatus), or causing a matching failure by an electric field generated from the outer surface of the metal part, the metal part may be in an electrically floating state instead of being grounded.

Also in the above embodiment, the wafer W is rotated by the rotary table 2 to pass through the areas P1, P2, and P3 in sequence. Alternatively, a continuous kiln where the areas P1, P2, and P3 are arranged in a straight line may be used. In this case, a movement mechanism such as a conveyor for conveying the wafer W may be used.

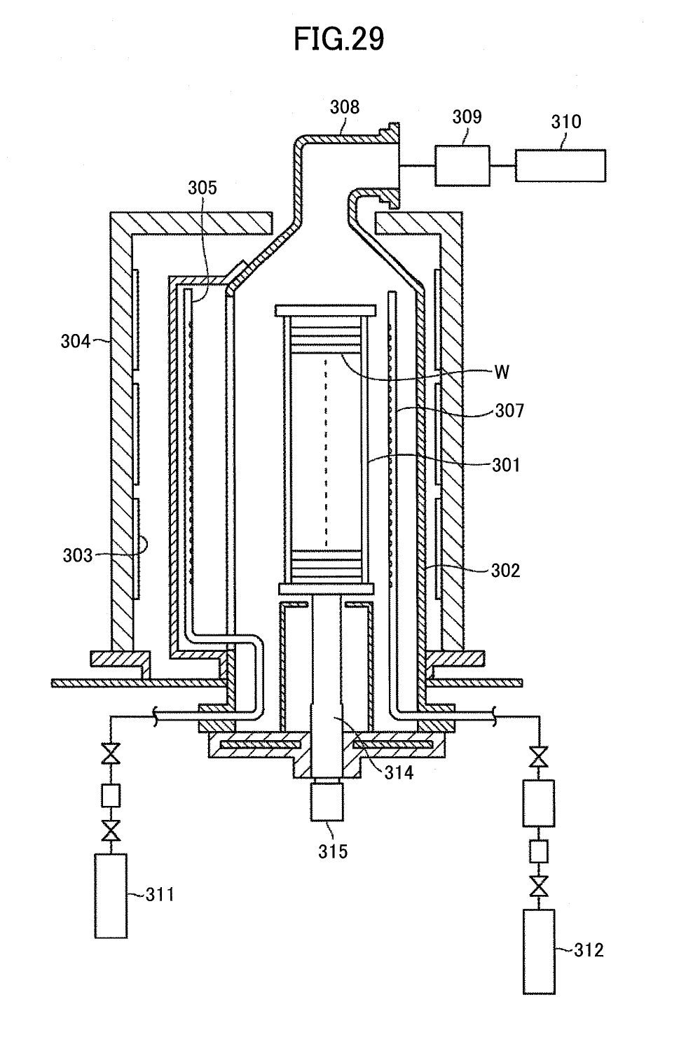

Next, an example where the present invention is applied to a batch apparatus is described with reference to FIGS. 29 through 31. The batch apparatus is a vertical heat treatment apparatus that performs a film deposition process on a large number of (e.g., 150) wafers W at the same time. The batch apparatus includes a wafer boat 301 where the wafers W are stacked like a shelf, and a reaction tube 302 that is a vertical process chamber for hermetically housing the wafer boat 301 and performing a film deposition process. A furnace body 304 is provided outside of the reaction tube 302, and heaters 303 are arranged in the circumferential direction on the inner wall of the furnace body 304.

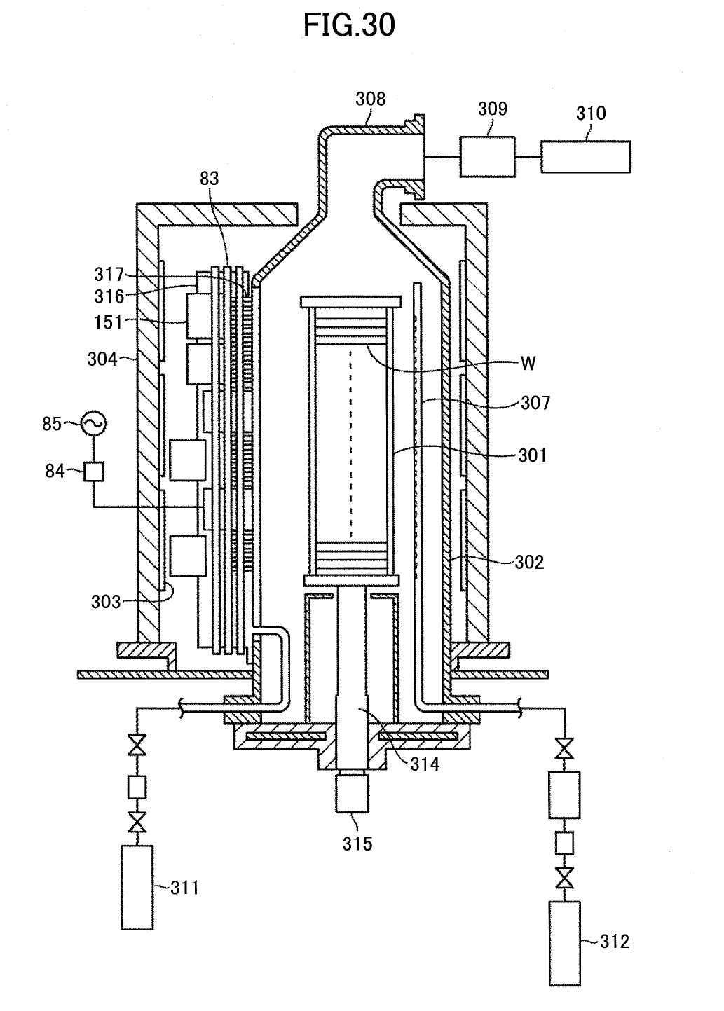

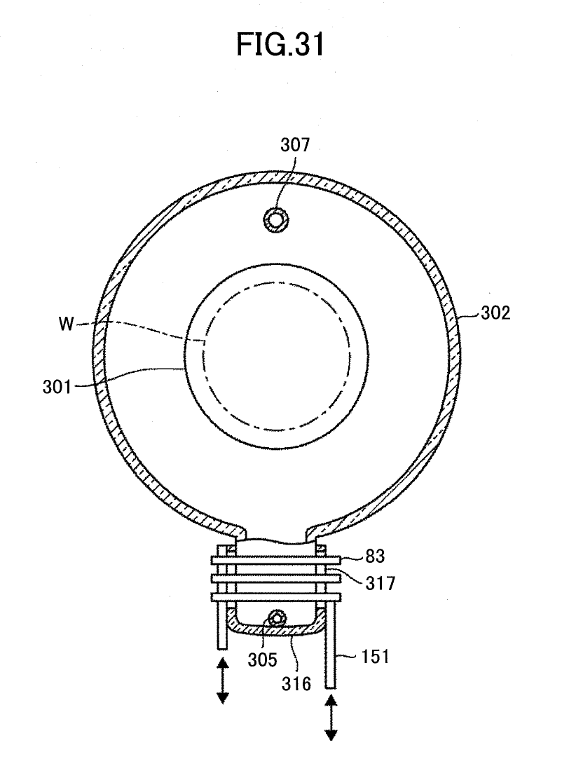

A part of the side surface of the reaction tube 302 projects outward to form a projecting part that extends vertically. As illustrated by FIGS. 29 and 31, a reaction gas injector 305 is provided in the projecting part of the reaction tube 302. The reaction gas injector 305 extends vertically and supplies an ammonia gas into the reaction tube 302. Also, a source gas injector 307 for supplying a source gas (Si-containing gas) is provided in the reaction tube 302. The source gas injector 307 extends vertically and faces the reaction gas injector 305 across the wafer boat 301. An evacuation port 308 is formed at the upper end of the reaction tube 302. The evacuation port 308 is connected via a pressure controller 309 to a vacuum pump 310 that is an evacuation mechanism for evacuating the reaction tube 302. In FIGS. 29 and 30, reference number 311 indicates an ammonia gas reservoir and reference number 312 indicates a source gas reservoir.

A rotational mechanism 315 such as a motor is connected via a rotational shaft 314 to the lower end of the wafer boat 301. The rotational mechanism 315 rotates the wafer boat 301 around the vertical axis. As illustrated by FIG. 30, an antenna 83 is wound vertically (or about the horizontal axis) around the outer surface of the projecting part where the reaction gas injector 305 is placed. Also, as illustrated by FIG. 31, a Faraday shield 316 composed of a grounded conductive plate is provided between the projecting part and the antenna 83, i.e., to cover the projecting part. Slits 317 extending horizontally and arranged vertically are formed in the Faraday shield 316.

Shutters 151 composed of grounded conductive plates are provided between the Faraday shield 316 and the antenna 83. Each of the shutters 151 is movable horizontally between a position close to the reaction tube 302 and a position away from the reaction tube 302 to adjust the opening area of the slits 317. In this example, six shutters 151 are arranged vertically on each side of the projecting part where the reaction gas injector 305 is placed. In other words, as illustrated by FIG. 31, pairs of shutters 151 are disposed to sandwich the projecting part. Also in this example, as illustrated by FIG. 31, the slits 317 are not formed in an area where the reaction gas injector 305 is placed. An insulator (not shown) composed of, for example, quartz is provided between the antenna 83, and the Faraday shield 316 and the shutters 151.

With the batch apparatus described above, multiple wafers W are stacked in the wafer boat 301, and the wafer boat 301 is hermetically placed in the reaction tube 302. Next, while maintaining the inside of the reaction tube 302 at a film deposition pressure, a source gas is supplied to the wafer boat 301 being rotated about the vertical axis so that the components of the source gas are adsorbed onto the surface of each wafer W. Next, after the atmosphere in the reaction tube 302 is replaced, the positions of the shutters 151 are adjusted to make the degree of plasma processing uniform in the vertical direction in the reaction tube 302.

Then, an ammonia gas is supplied from the reaction gas injector 305 into the reaction tube 302, and the ammonia gas is activated by the magnetic component generated by the antenna 83 to generate plasma. When the plasma is supplied to each wafer W, the components of the source gas adsorbed onto the surface of the wafer W are nitrided. The atmosphere in the reaction tube 302 is replaced again, and the adsorption and nitridation of the source gas are repeated to form a thin film made of silicon nitride. Thus, also with the configuration of the batch apparatus described above, it is possible to make the degree of plasma processing uniform in the vertical direction in the reaction tube 302.

In addition to the semi-batch apparatus (the plasma process apparatus) and the batch apparatus that process multiple wafers W concurrently, the present invention may also be applied to a single-wafer processing apparatus. In the case of a single-wafer processing apparatus, an antenna is disposed above a vacuum chamber to face a holding part where a wafer W is placed. The antenna may be wound multiple times in, for example, a spiral pattern from the center of the wafer W toward the outer edge of the wafer W. A Faraday shield composed of a grounded conductive plate is provided between the antenna and the vacuum chamber. Slits are formed in the Faraday shield such that the slits extend along the length direction of the antenna and intersect with (or become orthogonal to) a direction in which the antenna extends. Multiple shutters are provided between the antenna and the Faraday shield. The shutters are arranged along the circumferential direction of the wafer and are movable horizontally in the circumferential direction of the wafer W.

In the single-wafer processing apparatus, a Si-containing gas and an ammonia gas are supplied alternately to the wafer W, and the atmosphere in the vacuum chamber is replaced when the gases are switched. When the ammonia gas is supplied into the vacuum chamber, the ammonia gas is converted into plasma by a magnetic field component generated by the antenna. By setting the positions of the shutters in advance, it is possible to adjust the amount of plasma in the circumferential direction of the wafer W as well as the amount of plasma in the radial direction of the wafer W.

In the above examples, an adsorption process of adsorbing an Si-containing gas onto the wafer W, a nitridation process of nitriding the Si-containing gas adsorbed onto the wafer W, and a plasma reforming process are performed. The present invention may also be applied to a case where a plasma reforming process is performed on a wafer W on which a thin film has already been formed.

Also in the above examples, shutters are provided between an antenna and a Faraday shield. Alternatively, the shutters may be disposed at a position that is closer to the wafer W than the Faraday shield. In the above embodiment, the slits 97 are formed to become orthogonal to the length direction of the antenna 83 (i.e., such that the antenna 83 and each slit 97 form an angle of 90 degrees). Alternatively, the slits 97 may be formed to interest with the length direction of the antenna 83 (the direction in which the slits 97 extend is not the same as the direction in which the antenna 83 extends).

As the first process gas, a bis(tertiary-butyl-amino)silane (BTBAS: SiH2(NH—C(CH3)3)2)) gas may be used instead of a DCS gas. Also, as the second process gas, an oxygen (O2) gas may be used instead of an ammonia gas. In this case, the oxygen gas is converted into plasma in the primary plasma generator 81, and a silicon oxide (Si—O) film is formed as a reaction product.

An aspect of this disclosure provides a plasma process apparatus and a plasma generating device where a plasma generating gas is converted into plasma using an antenna and makes it possible to adjust the degree of plasma processing in the length direction of the antenna.

According to an aspect of this disclosure, a Faraday shield, which is composed of a conductive plate where multiple slits are formed, is provided between an antenna and a plasma generating area to block an electric field in an electromagnetic field generated by the antenna and to allow a magnetic field in the electromagnetic field. Also, an adjusting part is provided between the antenna and the Faraday shield to adjust the opening area of the slits. This configuration makes it possible to adjust the plasma density in the length direction of the antenna, and thereby makes it possible to make the degree of plasma processing uniform across the surface of a substrate.

A plasma process apparatus and a plasma generating apparatus according to the embodiments are described above. However, the present invention is not limited to the specifically disclosed embodiments, and variations and modifications may be made without departing from the scope of the present invention.

What is claimed is:

1. A plasma process apparatus, comprising:
a vacuum chamber;
a substrate holder disposed in the vacuum chamber and configured to hold a substrate;
a gas supplying part configured to supply a plasma generating gas into the vacuum chamber;
an antenna configured to be supplied with a high-frequency power and generate an electromagnetic field for generating plasma of the plasma generating gas;
a Faraday shield disposed between the antenna and an area where the plasma is generated and composed of a conductive plate where a plurality of slits are formed to block an electric field in the electromagnetic field generated by the antenna and to allow a magnetic field in the electromagnetic field to pass therethrough, wherein the slits extend in a direction that intersects with an extending direction in which the antenna extends and are arranged in the extending direction of the antenna; and
an adjusting part composed of a conductive material and configured to adjust an opening area of the slits.

2. The plasma process apparatus as claimed in claim 1, wherein
the gas supplying part is a gas nozzle that extends in the length direction of the antenna; and
the slits are formed such that the antenna is not visible through the slits from a side of the gas nozzle.

3. The plasma process apparatus as claimed in claim 1, further comprising:
a movement mechanism configured to move the substrate holder relative to an assembly including the gas supplying part, the antenna, the Faraday shield, and the adjusting part, during plasma processing.

4. The plasma process apparatus as claimed in claim 3, wherein
the substrate holder is a rotary table configured to rotate the substrate around a center of rotation of the rotary table;
the movement mechanism is a rotating mechanism configured to rotate the rotary table; and
the antenna extends from a center side toward an outer side of the rotary table.

5. The plasma process apparatus as claimed in claim 4,
wherein the vacuum chamber includes an upper surface a part of which protrudes upward to form a protruding part that forms the area where the plasma is generated, the protruding part extending from the center side toward the outer side of the rotary table;
wherein the antenna is disposed to surround the protruding part in plan view, the gas supplying part is housed in the protruding part, and the Faraday shield constitutes a part of side surfaces of the protruding part;
wherein the side surfaces of the protruding part includes an inner side surface facing the center side of the rotary table, an outer side surface facing the outer side of the rotary table, an upstream side surface facing upstream in a rotational direction of the rotary table, and a downstream side surface facing downstream in the rotational direction of the rotary table; and
wherein the slits are not formed in the inner side surface and the outer side surface, or a density of the slits formed in the inner side surface and the outer side surface is less than a density of the slits formed in the upstream side surface and the downstream side surface.

6. The plasma process apparatus as claimed in claim 1, wherein the adjusting part comprises a plurality of adjusting parts arranged along the length direction of the antenna.

7. The plasma process apparatus as claimed in claim 5,
wherein the adjusting part comprises a plurality of adjusting parts arranged on the upstream side surface and the downstream side surface; and
a number of the adjusting parts arranged on the upstream side surface is different from a number of the adjusting parts arranged on the downstream side surface.

8. The plasma process apparatus as claimed in claim 4, further comprising:
a process gas nozzle disposed apart from the gas supplying part in a circumferential direction of the vacuum chamber and configured to supply a process gas to be adsorbed onto the substrate; and
a separation gas nozzle configured to supply a separation gas to a separation area for separating an area where the plasma generating gas is supplied and an area where the process gas is supplied,
wherein the gas supplying part is a nozzle configured to supply a reaction gas for generating an active species that reacts with a component of the process gas adsorbed onto the substrate.

9. The plasma process apparatus as claimed in claim 4, further comprising:
a plurality of process gas nozzles disposed apart from the gas supplying part in a circumferential direction of the vacuum chamber and configured to supply process gases that react with each other to form a reaction product on a surface of the substrate; and
a separation gas nozzle configured to supply a separation gas to a separation area for separating areas where the process gases are supplied,
wherein the gas supplying part is a nozzle configured to supply a gas for generating an active species for reforming the reaction product formed on the surface of the substrate.

10. The plasma process apparatus as claimed in claim 1, further comprising:
a memory configured to store data that associates types of processes to be performed on the substrate with positions of the adjusting part; and
a control unit configured to read one of the positions of the adjusting part corresponding to a selected one of the types of processes and output a control signal according to the read one of the positions to a drive mechanism for moving the adjusting part.

11. A plasma generating device, comprising:
a gas supplying part configured to supply a plasma generating gas into a vacuum atmosphere;
an antenna configured to be supplied with a high-frequency power and generate an electromagnetic field for generating plasma of the plasma generating gas;
a Faraday shield disposed between the antenna and an area where the plasma is generated and composed of a conductive plate where a plurality of slits are formed to block an electric field in the electromagnetic field generated by the antenna and to allow a magnetic field in the electromagnetic field to pass therethrough, wherein the slits extend in a direction that intersects with an extending direction in which the antenna extends and are arranged in the extending direction of the antenna; and
an adjusting part composed of a conductive material and configured to adjust an opening area of the slits.
